(19) United States
(12) Patent Application Publication
(10) Pub. No.: US 2026/0266887 A1
(43) Pub. Date: Sep. 10, 2026

(54) SENSING APPARATUS, SYSTEM AND METHOD FOR REDUCING ELECTROMAGNETIC INTERFERENCE IN ELECTRIC UTILITY GRID MONITORING SYSTEM

(71) Applicant: Safegrid Oy, Espoo (FI)

(72) Inventors: Tapio Mäntysalo, Hevonpää (FI); Jussi Hakunti, Parainen (FI); Ville Peltoniemi, Piikkiö (FI)

(73) Assignee: Safegrid Oy, Espoo (FI)

(21) Appl. No.: 19/552,115

(22) Filed: Feb. 27, 2026

Related U.S. Application Data
(63) Continuation-in-part of application No. 18/245,433, filed on Jan. 10, 2023, now Pat. No. 12,566,207.

(30) Foreign Application Priority Data
Jan. 17, 2022 (FI) 20225035

(51) Int. Cl. G01R 31/08; G01R 15/20

(52) U.S. Cl. CPC G01R 31/085; G01R 15/207

(57) ABSTRACT

A sensing apparatus for an electric utility grid is disclosed. The sensing apparatus includes at least one magnetic field sensor device arranged to sense a magnetic field in close proximity to electrical overhead lines to generate first sensor data, and at least one processor communicably coupled to the at least one magnetic field sensor device. The sensing apparatus further includes at least one magnetic noise source located within a housing of the sensing apparatus or outside the housing. The at least one magnetic field sensor device is oriented relative to the at least one magnetic noise source such that a direction of minimum magnetic field sensitivity of the at least one magnetic field sensor device is aligned toward the at least one magnetic noise source, thereby reducing magnetic interference coupled into the first sensor data. The processor pre-processes the first sensor data to generate measurement data representative of magnetic fields produced by electrical currents flowing through the electrical overhead lines and utilizes the measurement data and the first sensor data to reproduce overhead line phase currents and to detect and manage currents, events, and faults in the electric utility grid.

### CROSS REFERENCE TO RELATED APPLICATION

This application is a continuation-in-part of U.S. patent application Ser. No. 18/245,433 filed Mar. 15, 2023. The said application is incorporated by reference herein.

### TECHNICAL FIELD

The present disclosure relates to sensing apparatuses. Moreover, the present disclosure also relates methods for reducing electromagnetic interference in electric utility grid monitoring. Furthermore, the present disclosure also relates to systems for reducing electromagnetic interference in electric utility grid monitoring. Furthermore, the present disclosure also relates to methods for installing a sensing apparatus in an electric utility grid. Furthermore, the present disclosure also relates to methods for predicting, monitoring, and managing events and faults in an electric utility grid.

### BACKGROUND

With the advent in usage of electricity worldwide, electric utility grids were installed to transmit electricity from an electricity generating plant to various consumers, including but not limited to households, factories, hospitals, offices, and schools. Such electric utility grids may be expansive enough to cover entire countries or continents to ensure electricity supply in each remote area, and not merely in cities. The electric utility grids consist of expansive transmission and distribution lines or cables which carry the electricity, and in case of overhead lines, electrical poles, which are installed at frequent distances to ensure that the electrical wires hang at a predetermined and safe height. The transmission and distribution lines carry high voltages of electricity and will cause fatalities to normal life if interfered with.

However, managing and maintaining such electric utility grids and ensuring an uninterrupted supply of electricity is quite difficult and associated with several limitations. Often, faults might happen in the electric utility grid due to a voltage disruption, natural elements, or outside interference. In such cases, such faults may damage the electric utility grid, and result in an interruption to electricity supply in certain areas which in turn may damage connected customers' equipment or property. In such cases, such faults may even lead to damage to life or property. Not only is it difficult to timely identify such faults, but it is also difficult to timely locate the fault to avoid damages or to predict locations for potential faults. Often, electric poles are located approximately 20 to 200 meters, and since current passes quickly through the distribution lines, it is difficult to narrow a fault location for fixing the fault. The presently available solutions utilize sensors to sense voltage and/or current in the distribution lines; however, these are neither accurate nor reliable and can be utilized for only a specific type of electric utility grid having a specific current being transmitted through the distribution lines.

Moreover, to identify fault conditions, and to protect life, property and equipment on electrical grid fault conditions, the electrical grid is required to be equipped with several different kinds of fault protection and fault indication devices, such as disconnectors, fuses, protection relays and fault indicators which may be manually or automatically operating with or without remote data connection to the electrical grid operation centre. For example, sensing the electrical fault status on an overhead line may require a current transformer installed over the wire. Solutions installable at secondary substation cabinets exist, as well as solutions where current transformers are attached to the high or medium voltage wires with varying solutions, typically radio transmission, to indicate line status. In addition, several attempts with variable economic success have been made to market devices and systems for detecting the line fault status from a distance of approximately 1 to 10 meters by using magnetic sensors (such as, coils, hall elements or silicon chip base MEMS sensors or Magnetoresistance (MR) sensors). Although such fault indication devices have the benefit of easy hot installation directly to the utility pole (i.e., it does not require for the electrical power supply to be switched off for installation), but they exponentially increased involved costs since fabricating such devices, assembling them as well as installing them are extremely expensive. Therefore, such systems have a restricted use, are expensive, and/or cannot be utilized for existing electric utility grids. Moreover, such solutions do not provide any insight on the location of faults for mitigating the same.

Furthermore, in compact pole-mounted sensing apparatuses for monitoring overhead lines, magnetic field sensor devices are often housed together with electronics such as power supplies, converters, microprocessors, digital devices, and wireless communication modules. Such electronics, and connected wiring such as power supply wiring, may generate internally sourced electromagnetic emissions (for example, switching transients and near-field magnetic leakage) that couple into the magnetic field sensor devices due to limited spacing within the enclosure. If not mitigated, this internally generated electromagnetic interference can degrade signal-to-noise ratio, distort measured magnetic field signals, and reduce the accuracy of current reconstruction and fault detection and localization. Conventional mitigation techniques such as shielding, filtering, or increased component separation may add cost and complexity, attenuate desired signal components, or be impractical in compact enclosures, and therefore improved approaches for reducing internally generated electromagnetic interference are needed.

Especially the low frequency, mains frequency and harmonics up to several megahertz or more, magnetic fields are very difficult or impossible to shield against at proximity. Shielding against low frequency magnetic field disturbances would require impractically thick shielding constructions that are not realizable in small spaces like electric device enclosures.

Therefore, in light of the foregoing discussion, there exists a need to overcome the aforementioned drawbacks associated with visibility, and specifically, drawbacks associated with reducing effect of electromagnetic interference during monitoring, identifying and locating events and faults in the electric utility grid.

### SUMMARY

The present disclosure seeks to provide a sensing apparatus. The present disclosure also seeks to provide a method for reducing electromagnetic interference in electric utility grid monitoring. Moreover, the present disclosure also seeks to provide a system for reducing electromagnetic interference in electric utility grid during monitoring. Furthermore, the present disclosure also seeks to provide a method for monitoring and managing events and faults in an electric utility grid. Furthermore, the present disclosure also seeks to provide a method for installing a sensing apparatus in an electric utility grid.

The present disclosure provides sensing apparatuses, systems, and methods in which internally or externally generated electromagnetic interference is reduced by intentionally orienting one or more magnetic field sensor devices relative to an identified magnetic noise source within a housing or enclosure or outside a housing or enclosure.

An aim of the present disclosure is to provide a solution that overcomes at least partially the problems encountered in prior art.

In one aspect, an embodiment of the present disclosure provides a sensing apparatus comprising:
at least one magnetic field sensor device that, in operation, senses a magnetic field in close proximity to electrical overhead lines of an electric utility grid to generate a first sensor data, wherein at least a portion of the sensing apparatus is arranged on an electrical pole of the electric utility grid;
at least one magnetic noise source including at least one internal magnetic noise source arranged within a housing of the sensing apparatus or at least one external magnetic noise source located outside the housing;
at least one processor communicably coupled to the at least one magnetic field sensor device;
wherein the at least one magnetic field sensor device is oriented relative to the at least one magnetic noise source such that a direction of minimum magnetic field sensitivity of the at least one magnetic field sensor device is aligned toward the at least one magnetic noise source; and
wherein the at least one processor in operation:
pre-processes the first sensor data to generate measurement data, the measurement data comprising values of magnetic field produced by electrical currents flowing through the electrical overhead lines; and
utilizes the measurement data and the first sensor data to reproduce overhead line phase currents, and to detect and manage currents, events, and faults in the electric utility grid.

In one aspect, an embodiment of the present disclosure provides a method for reducing electromagnetic interference in a sensing apparatus installed on an electrical pole of an electric utility grid, the method comprising:
identifying at least one magnetic noise source located within a housing of the sensing apparatus or outside the housing of the sensing apparatus;
determining a direction of minimum magnetic field sensitivity of each magnetic field sensor device within the housing;
orienting the at least one magnetic field sensor device relative to the at least one magnetic noise source such that a direction of minimum magnetic field sensitivity of the at least one magnetic field sensor device is aligned toward the at least one magnetic noise source; and
sensing magnetic fields generated by electrical overhead lines while reducing electromagnetic interference from the magnetic noise source.

In yet another aspect, an embodiment of the present disclosure provides a method for installing a sensing apparatus in an electric utility grid, comprising:
arranging at least one magnetic field sensor device, at least one magnetic noise source including at least one internal magnetic noise source or at least one external magnetic noise source, and at least one processor of the sensing apparatus in a housing when the housing is arranged on an electrical pole;
obtaining information regarding a configuration of electrical overhead lines with respect to the electrical pole; and
arranging the sensing apparatus based on the configuration of the electrical overhead lines, such that:
the sensing apparatus is arranged horizontally with respect to the electrical pole, when the configuration of the electrical overhead lines with respect to the electrical pole is a vertical configuration;
the sensing apparatus is arranged vertically with respect to the electrical pole, when the configuration of the electrical overhead lines with respect to the electrical pole is a horizontal configuration;
the sensing apparatus is arranged to be suspended from one or more of the electrical overhead lines; or
the sensing apparatus is arranged to be suspended from one or more of the electrical overhead lines, such that the sensing apparatus is powered by the electrical overhead lines.

In yet another aspect, an embodiment of the present disclosure provides a system for reducing electromagnetic interference in a sensing apparatus installed on an electrical pole of an electric utility grid and for monitoring and managing events and faults in an electric utility grid, the system comprising:
at least one sensing apparatus comprising:
at least one magnetic field sensor device that, in operation, senses magnetic field in close proximity to electrical overhead lines of an electric utility grid to generate a first sensor data, wherein at least a portion of the sensing apparatus is arranged on an electrical pole of the electric utility grid;
at least one magnetic noise source including at least one internal magnetic noise source arranged within a housing of the sensing apparatus or at least one external magnetic noise source located outside the housing;
at least one processor communicably coupled to the at least one magnetic field sensor device;
wherein the at least one magnetic field sensor device is oriented relative to the at least one magnetic noise source such that a direction of minimum magnetic field sensitivity of the at least one magnetic field sensor device is aligned toward the at least one magnetic noise source; and
wherein the at least one processor in operation:

identifies the at least one magnetic noise source of the sensing apparatus to determine a direction of minimum magnetic field sensitivity of at least one magnetic field sensor for orienting the magnetic field sensor such that the direction of minimum magnetic field sensitivity is aligned toward the magnetic noise source;
pre-processes the first sensor data to generate measurement data, the measurement data comprising values of magnetic field produced by electrical currents flowing through the electrical overhead lines;
utilizes the measurement data and the first sensor data to reproduce overhead line phase currents, to detect, classify and locate an event or a fault that has occurred in the electric utility grid; and/or
predicts when and where an event or a fault is likely to occur in the electric utility grid; and
alerts a network operator of the detected or predicted event or fault and its location.

In still another aspect, an embodiment of the present disclosure provides a method for monitoring and managing events and faults in an electric utility grid, the method comprising:
sensing, using at least one magnetic field sensor device of a sensing apparatus, a magnetic field in close proximity to electrical overhead lines of the electric utility grid for generating a first sensor data, wherein the sensing apparatus being at least partially arranged on an electrical pole;
processing, by at least one processor of the sensing apparatus, the first sensor data to generate measurement data, the measurement data comprising values of magnetic field produced by electrical currents flowing through the electrical overhead lines;
utilizing the measurement data and the first sensor data to reproduce overhead line phase currents; and
processing the measurement data to:
detect and locate an event or a fault that has occurred in the electric utility grid; and/or
predict when and where an event or a fault is likely to occur in the electric utility grid.

Additional aspects, advantages, features, and objects of the present disclosure would be made apparent from the drawings and the detailed description of the illustrative embodiments construed in conjunction with the appended claims that follow.

It will be appreciated that features of the present disclosure are susceptible to being combined in various combinations without departing from the scope of the present disclosure as defined by the appended claims.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those skilled in the art will understand that the drawings are not to scale. Wherever possible, like elements have been indicated by identical numbers.

Embodiments of the present disclosure will now be described, by way of example only, with reference to the following diagrams wherein:

FIG. 1 illustrates a block diagram of an architecture of a sensing apparatus, in accordance with an embodiment of the present disclosure;

FIGS. 2A-2D illustrate arrangements of sensor devices in a sensing apparatus, in accordance with different embodiments of the present disclosure;

FIGS. 3A and 3B are exemplary schematic illustrations of a housing of a sensing apparatus, in accordance with different embodiments of the present disclosure;

FIGS. 4A and 4B illustrate arrangements of a sensing apparatus with respect to an electrical pole, in accordance with different embodiments of the present disclosure;

FIG. 5 is an exemplary schematic illustration of sensing apparatuses with respect to electrical poles of an electric utility grid, in accordance with an embodiment of the present disclosure;

FIG. 6 is an exemplary illustration of a measurement configuration of a sensing apparatus, in accordance with an embodiment of the present disclosure;

FIGS. 7A and 7B are exemplary illustrations of a magnetic field sensor, in accordance with an embodiment of the present disclosure;

FIGS. 8A and 8B illustrates steps of a method for installing a sensing apparatus in an electric utility grid, in accordance with an embodiment of the present disclosure;

FIG. 9 illustrates an architecture of a system for monitoring and managing events and faults in an electric utility grid, in accordance with an embodiment of the present disclosure;

FIG. 10 illustrates an architecture of a system for monitoring and managing events and faults in an electric utility grid, in accordance with another embodiment of the present disclosure;

FIGS. 11A-11C illustrate different waveforms of current transients, in accordance with various embodiments of the present disclosure;

FIG. 12 illustrates steps of a method for monitoring and managing events and faults in an electric utility grid, in accordance with an embodiment of the present disclosure;

FIGS. 13A-13C are exemplary simulations for a configuration of the sensing apparatus with respect to electrical overhead lines, in accordance with an embodiment of the present disclosure;

FIGS. 14A-14C are exemplary simulations for a configuration of the sensing apparatus with respect to electrical overhead lines, in accordance with another embodiment of the present disclosure;

FIGS. 15A-15C are exemplary simulations for a configuration of the sensing apparatus with respect to electrical overhead lines, in accordance with yet another embodiment of the present disclosure; and

FIGS. 16A-16E are exemplary simulations for a configuration of the sensing apparatus for reducing electromagnetic interference, in accordance with yet another embodiment of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practising the present disclosure are also possible.

In a first aspect, an embodiment of the present disclosure provides a sensing apparatus comprising:
at least one magnetic field sensor device that, in operation, senses a magnetic field in close proximity to electrical overhead lines of an electric utility grid to generate a first sensor data, wherein at least a portion of the sensing apparatus is arranged on an electrical pole of the electric utility grid;
at least one magnetic noise source including at least one internal magnetic noise source arranged within a housing of the sensing apparatus or at least one external magnetic noise source located outside the housing;
at least one processor communicably coupled to the at least one magnetic field sensor device;
wherein the at least one magnetic field sensor device is oriented relative to the at least one magnetic noise source such that a direction of minimum magnetic field sensitivity of the at least one magnetic field sensor device is aligned toward the at least one magnetic noise source; and
wherein the at least one processor in operation:
pre-processes the first sensor data to generate measurement data, the measurement data comprising values of magnetic field produced by electrical currents flowing through the electrical overhead lines; and
utilizes the measurement data and the first sensor data to reproduce overhead line phase currents, and to detect and manage currents, events, and faults in the electric utility grid.

In one aspect, an embodiment of the present disclosure provides a method for reducing electromagnetic interference in a sensing apparatus installed on an electrical pole of an electric utility grid, the method comprising:
identifying at least one magnetic noise source located within a housing of the sensing apparatus or outside the housing of the sensing apparatus;
determining a direction of minimum magnetic field sensitivity of each magnetic field sensor device within the housing;
orienting the at least one magnetic field sensor device relative to the at least one magnetic noise source such that a direction of minimum magnetic field sensitivity of the at least one magnetic field sensor device is aligned toward the at least one magnetic noise source; and
sensing magnetic fields generated by electrical overhead lines while reducing electromagnetic interference from the magnetic noise source.

In a second aspect, an embodiment of the present disclosure provides a method for installing a sensing apparatus in an electric utility grid, comprising:
arranging at least one magnetic field sensor device, at least one magnetic noise source including at least one internal magnetic noise source or at least one external magnetic noise source, and at least one processor of the sensing apparatus in a housing when the housing is arranged on an electrical pole;
obtaining information regarding a configuration of electrical overhead lines with respect to the electrical pole; and
arranging the sensing apparatus based on the configuration of the electrical overhead lines, such that:
the sensing apparatus is arranged horizontally with respect to the electrical pole, when the configuration of the electrical overhead lines with respect to the electrical pole is a vertical configuration;
the sensing apparatus is arranged vertically with respect to the electrical pole, when the configuration of the electrical overhead lines with respect to the electrical pole is a horizontal configuration;
the sensing apparatus is arranged to be suspended from one or more of the electrical overhead lines; or
the sensing apparatus is arranged to be suspended from one or more of the electrical overhead lines, such that the sensing apparatus is powered by the electrical overhead lines.

In a third aspect, an embodiment of the present disclosure provides a system for reducing electromagnetic interference in a sensing apparatus installed on an electrical pole of an electric utility grid and for monitoring and managing events and faults in an electric utility grid, the system comprising:
at least one sensing apparatus comprising:
at least one magnetic field sensor device that, in operation, senses magnetic field in close proximity to electrical overhead lines of an electric utility grid to generate a first sensor data, wherein at least a portion of the sensing apparatus is arranged on an electrical pole of the electric utility grid;
at least one magnetic noise source including at least one internal magnetic noise source arranged within a housing of the sensing apparatus or at least one external magnetic noise source located outside the housing;
at least one processor communicably coupled to the at least one magnetic field sensor device;
wherein the at least one magnetic field sensor device is oriented relative to the at least one magnetic noise source such that a direction of minimum magnetic field sensitivity of the at least one magnetic field sensor device is aligned toward the at least one magnetic noise source; and
wherein the at least one processor in operation:
identifies the at least one magnetic noise source of the sensing apparatus to determine a direction of minimum magnetic field sensitivity of at least one magnetic field sensor for orienting the magnetic field sensor such that the direction of minimum magnetic field sensitivity is aligned toward the magnetic noise source;
pre-processes the first sensor data to generate measurement data, the measurement data comprising values of magnetic field produced by electrical currents flowing through the electrical overhead lines;
utilizes the measurement data and the first sensor data to reproduce overhead line phase currents, to detect, classify and locate an event or a fault that has occurred in the electric utility grid; and/or
predicts when and where an event or a fault is likely to occur in the electric utility grid; and
alerts a network operator of the detected or predicted event or fault and its location.

In a fourth aspect, an embodiment of the present disclosure provides a method for monitoring and managing events and faults in an electric utility grid, the method comprising:
sensing, using at least one magnetic field sensor device of a sensing apparatus, a magnetic field in close proximity to electrical overhead lines of the electric utility grid for generating a first sensor data, wherein the sensing apparatus being at least partially arranged on an electrical pole;
processing, by at least one processor of the sensing apparatus, the first sensor data to generate measurement data, the measurement data comprising values of magnetic field produced by electrical currents flowing through the electrical overhead lines;
utilizing the measurement data and the first sensor data to reproduce overhead line phase currents; and
processing the measurement data to:
detect and locate an event or a fault that has occurred in the electric utility grid; and/or
predict when and where an event or a fault is likely to occur in the electric utility grid.

The magnetic noise source alignment described herein is independent of the geometric arrangement of the magnetic field sensor devices. The alignment of a direction of minimum magnetic field sensitivity toward a magnetic noise source may be implemented in sensing apparatuses comprising a single magnetic field sensor device, a plurality of spatially separated magnetic field sensor devices, or a plurality of magnetic field sensor devices arranged in a cross-positioned or overlapping configuration.

In an embodiment of the present disclosure provides a sensing apparatus comprising:
at least a first sensor device, a second sensor device, and a third sensor device that, in operation, sense magnetic field in close proximity to electrical overhead lines of an electric utility grid to generate sensor data, wherein at least a portion of the sensing apparatus is arranged on an electrical pole of the electric utility grid, wherein
the second sensor device overlaps with the first sensor device to form a cross-positioned two-sensor configuration; and
the third sensor device is arranged at a distance from the cross-positioned two-sensor configuration; and
a first processor configured to:
pre-process the sensor data and send the sensor data to a second processor;
generate measurement data, the measurement data comprising values of magnetic field produced by electrical currents flowing through the electrical overhead lines; and
send, to at least one second processor, the measurement data and the sensor data, for reproducing overhead line phase currents, wherein the second processor is configured to send, to at least one third processor, the measurement data, wherein the at least one third processor, in operation, utilizes the measurement data, for monitoring and managing currents, events and faults in the electric utility grid.

In an embodiment of the present disclosure provides a method for installing a sensing apparatus in an electric utility grid, comprising:
arranging at least a first sensor device, a second sensor device, a third sensor device, and a first processor of the sensing apparatus in a housing such that when the housing is arranged on an electrical pole:
the second sensor device overlaps with the first sensor device to form a cross-positioned two-sensor configuration, and
the third sensor device is arranged at a distance from the cross-positioned two-sensor configuration;
obtaining information regarding a configuration of electrical overhead lines with respect to the electrical pole; and
arranging the sensing apparatus based on the configuration of the electrical overhead lines, such that:
the sensing apparatus is arranged horizontally with respect to the electrical pole, when the configuration of the electrical overhead lines with respect to the electrical pole is a vertical configuration;
the sensing apparatus is arranged vertically with respect to the electrical pole, when the configuration of the electrical overhead lines with respect to the electrical pole is a horizontal configuration;
the sensing apparatus is arranged to be suspended from one or more of the electrical overhead lines; or
the sensing apparatus is arranged to be suspended from one or more of the electrical overhead lines, such that the sensing apparatus is powered by the electrical overhead lines.

In an embodiment of the present disclosure provides a system for monitoring and managing events and faults in an electric utility grid, the system comprising:
at least one sensing apparatus comprising:
at least a first sensor device, a second sensor device, and a third sensor device that, in operation, sense magnetic field in close proximity to electrical overhead lines of the electric utility grid to generate sensor data, wherein at least a portion of the sensing apparatus is arranged on an electrical pole of the electric utility grid, and wherein
the second sensor device overlaps with the first sensor device to form a cross-positioned two-sensor configuration; and
the third sensor device is arranged at a distance from the cross-positioned two-sensor configuration; and
a first processor configured to pre-process the sensor data and send the sensor data to a second processor, generate measurement data, the measurement data comprising values of currents flowing through the electrical overhead lines;
at least one second processor communicably coupled to the first processor, wherein the at least one second processor is configured to:
receive, from the first processor, the sensor data pre-processed by the first processor, and the measurement data; and
process the measurement data and the sensor data to reproduce overhead line phase currents;
at least one third processor communicably coupled to the first processor and the second processor, wherein the at least third processor is configured to:
receive, from the second processor, the measurement data;
process the measurement data to:
detect, classify, and locate an event or a fault that has occurred in the electric utility grid; and/or
predict when and where an event or a fault is likely to occur in the electric utility grid; and
alert a network operator of the detected or predicted event or fault and its location.

In an embodiment of the present disclosure provides a method for monitoring and managing events and faults in an electric utility grid, the method comprising:
sensing, using at least a first sensor device, a second sensor device and a third sensor device of at least one sensing apparatus, magnetic field in close proximity to electrical overhead lines of the electric utility grid for generating sensor data;
processing the sensor data for generating measurement data, the measurement data comprising values of currents flowing through the electrical overhead lines;
receiving, from the at least one sensing apparatus, the measurement data;
processing the measurement data and the sensor data for reproducing overhead line phase currents; and
processing the measurement data for:
detecting and locating an event or a fault that has occurred in the electric utility grid; and/or
predicting when and where an event or a fault is likely to occur in the electric utility grid.

The present disclosure provides the aforementioned sensing apparatus, the aforementioned method for reducing electromagnetic interference, and the aforementioned system for reducing electromagnetic interference. The aforementioned sensing apparatus, the method and the system provide the technical advantage of improving magnetic-field-based overhead line monitoring in compact pole-mounted installations by reducing internally or externally generated electromagnetic interference through intentional orientation of each magnetic field sensor device such that its direction of minimum magnetic sensitivity is aligned toward a magnetic noise source (internal or external) within the enclosure. This reduces coupling of emissions (for example, from power conversion and wireless communication circuitry) into the sensor measurement path, thereby improving signal-to-noise ratio and measurement fidelity of magnetic fields produced by overhead line currents, enabling more accurate generation of measurement data and reproduction of overhead line phase currents, and increasing the reliability and accuracy of downstream fault detection, classification, and localization, while avoiding or reducing reliance on bulky shielding, aggressive filtering that may distort desired signals, or increased enclosure size that is impractical for pole-mounted deployments.

Additionally, the present disclosure provides the aforementioned sensing apparatus, the aforementioned method for installing the sensing apparatus in the electric utility grid, the aforementioned system for monitoring and managing events and faults in the electric utility grid, and the aforementioned method for monitoring and managing events and faults in the electric utility grid. Herein, sensing apparatuses are installed at electrical poles of the electric utility grid. These sensing apparatuses sense current (i.e., electric current) flowing through the electrical overhead lines and generate the measurement data to detect events and faults in the electric utility grid. In one or more embodiments sensor devices comprised in the sensing apparatus have the cross-positioned two-sensor configuration which improves measurement accuracy, measurement quality, and provides a compact electronic device. Processors of the system utilize the measurement data to not only detect and locate events and faults occurring in the electric utility grid, but also to predict events and faults that are likely to occur in the future. The sensing apparatuses allow increased visibility into the electric utility grid and assists in timely detecting and locating events and faults. This considerably reduces costs, time requirements, and ensures that uninterrupted flow of electricity is maintained.

Throughout the present disclosure, the term “sensing apparatus” refers to an apparatus which senses presence and magnitude of a magnetic field in its vicinity. The sensing apparatus comprises a plurality of sensor devices, such that sensor data generated from the plurality of sensor devices includes sensor data for magnetic field in each dimension.

Throughout the present disclosure, the term “sensor device” refers to a device which senses presence and magnitude of a magnetic field in a given plane. In particular, the sensor device refers to at least one magnetic field sensor device.

Moreover, the sensor device (namely, at least one magnetic field sensor device) generates the sensor data, namely a first sensor data, based on the sensed presence and magnitude of the magnetic field. The term “first sensor data” refers to data signals produced by the magnetic field sensor device that are indicative of the sensed magnetic field in close proximity to the electrical overhead lines and may include raw sensor measurements and/or processed values corresponding to magnetic field strength, direction, or variations over time, for use in generating measurement data representative of currents flowing through the electrical overhead lines.

The electrical overhead lines refer to one or more uninsulated electrical cables suspended by the electric pole, for electric power transmission and distribution to transmit electrical energy across large distances. The electrical overhead lines transmit electricity of high voltages, which when interacted with, may cause damage. Optionally, the electrical overhead lines are made of a plurality of wires of conducting material wrapped in a non-conductive and non-corrosive material. For example, a plurality metal wires wrapped in plastic. Moreover, each electrical overhead line comprises a plurality of wires. Herein, the wires are together to form the electrical overhead line. In an example, the electrical overhead line may have three wires. The electrical pole is a column used to support the electrical overhead lines, such that the electrical overhead lines are suspended in air using the electrical pole(/s), at a predefined distance from the ground, such that the electrical overhead lines do not cause damage to life or property. Optionally, the electrical pole is made of at least one of: cement, wood, metals, resin.

Optionally, a given sensor device comprises:
a magnetic field sensor; and
a measurement apparatus arranged in a circuit including the magnetic field sensor, wherein the measurement apparatus, in operation, measures an induced current in the circuit, the sensor data comprising values of the induced current in the circuit,
   wherein when processing the sensor data to generate the measurement data, the first processor is configured to:
determine values of magnetic field densities produced by electrical current in the electrical overhead lines; and
determine the values of currents flowing through the electrical overhead lines, based on the values of the magnetic field densities measured by the sensors and the directivity and orientation of the sensors and distance and position of the electrical overhead lines from the sensors.

Herein, the term “magnetic field sensor device” or “magnetic field sensor” refers to a sensing component configured to detect the presence, magnitude, and/or directional characteristics of a magnetic field in its vicinity and to generate sensor data representative of the sensed magnetic field. In other words, the magnetic field sensor refers to a sensor capable of sensing a magnetic field. Optionally, the magnetic field sensor detects an electromechanical field. Optionally, the magnetic field sensor device comprises one or more magnetic field sensing elements, such as a coil-based sensor, a Hall-effect sensor, a magnetoresistive sensor, or a micro-electro-mechanical systems sensor (MEMS) based magnetic sensor, together with associated measurement circuitry for producing electrical signals corresponding to magnetic fields generated by electrical currents flowing through overhead line conductors. Moreover, the measurement apparatus refers to an apparatus which measures a value of the magnetic field sensed by the magnetic field sensor, by way of measuring an induced current in the circuit. In operation, the magnetic field sensor senses a magnetic field, which is measured by the measurement apparatus. Induced current refers to current being induced in the circuit, due to the magnetic field caused by the voltage transmitting through the electrical overhead lines. Optionally, the sensor device further comprises an anti-disturbance filter, an amplifier, a digitizer, an optical transmitter and/or a radio transmitter. Beneficially, this helps to reduce disturbances in measuring the magnetic field. Optionally, the sensor device may comprise one or more sensor devices depending on the requirements. For example, the sensor device may comprise at least a first sensor device, a second sensor device, and a third sensor device, configured to be positioned in a specific manner relative to each other and relative to the electrical overhead lines. It will be appreciated that, optionally, the first sensor device is implemented as a first magnetic sensor device, the second sensor device is implemented as a second magnetic sensor device, and the third sensor device is implemented as a third magnetic sensor device.

Optionally, the at least one magnetic field sensor device comprises: a first magnetic field sensor device, a second magnetic field sensor device, a third magnetic field sensor device, and wherein the first magnetic field sensor, the second magnetic field sensor, and the third magnetic field sensor are oriented at mutually different angles relative to each other. In this regard, the at least one magnetic field sensor device may comprise a plurality of magnetic field sensor devices, including the first magnetic field sensor device, the second magnetic field sensor device, and the third magnetic field sensor device. In such embodiments, the first magnetic field sensor device, the second magnetic field sensor device, and the third magnetic field sensor device are oriented at mutually different angles relative to each other, meaning that the sensing axes or directions of maximum magnetic sensitivity of the respective sensor devices are not parallel but instead are arranged with different angular orientations in three-dimensional space. For example, the magnetic field sensor devices may be mounted such that their sensing directions are orthogonal or otherwise separated by predetermined angles (for instance, approximately 30°, 45°, 60°, or) 90° to enable sensing of magnetic field components along different directions. This multi-angle orientation allows the sensing apparatus to capture directional variations of magnetic fields generated by different overhead line conductors and improves the ability of the processor to distinguish and reconstruct phase currents from combined sensor measurements. The technical advantage is that orienting multiple magnetic field sensor devices at mutually different angles enhances measurement robustness, improves current reconstruction accuracy, and reduces ambiguity in fault detection and localization, particularly in complex overhead line configurations where magnetic field contributions overlap.

Optionally, a given magnetic field sensor device is coupled to a measurement apparatus arranged in a circuit including the given magnetic field sensor device, wherein the measurement apparatus, in operation, measures an induced current in the circuit, the sensor data comprising values of the induced current in the circuit,
wherein when processing the sensor data to generate the measurement data, the at least one processor is configured to:
determine values of magnetic field densities produced by electrical current in the electrical overhead lines; and
determine the values of currents flowing through the electrical overhead lines, based on the values of the magnetic field densities measured by the sensors and the directivity and orientation of the sensors and distance and position of the electrical overhead lines from the sensors.

Herein, the measurement apparatus refers to circuitry configured to convert the magnetic response of the sensor device into measurable electrical signals, for example by measuring an induced current or voltage generated in the circuit when the magnetic field sensor device is exposed to a magnetic field produced by currents flowing through the electrical overhead lines. In operation, the magnetic field sensor device senses the magnetic field in its vicinity, and the measurement apparatus measures the corresponding induced current in the circuit, such that the sensor data comprises values of the induced current and/or related signal parameters over time.

When processing the sensor data to generate the measurement data, the at least one processor (defined later) is configured to determine values of magnetic field densities produced by electrical current in the electrical overhead lines, for example by applying calibration factors and sensor response characteristics to the induced current measurements. The processor is further configured to determine values of currents flowing through the electrical overhead lines based on the measured magnetic field densities and the known directivity and orientation of the sensors, as well as the distance and relative position of the overhead line conductors with respect to the sensor devices. For example, the processor may employ mathematical relationships or matrix-based reconstruction techniques that relate sensor outputs to conductor currents using geometric parameters and sensor directional gain. The technical advantage is that this configuration enables non-contact, accurate estimation of overhead line phase currents from magnetic field measurements, thereby supporting reliable detection, classification, and localization of faults and events in the electric utility grid.

Throughout the present disclosure, the term “processor” or “at least one processor” refers to hardware, software, firmware, or a combination of these configured to control operation of the aforementioned sensing apparatus or system. In this regard, the processor performs several complex data processing tasks. The processor is communicably coupled to the sensing apparatus wirelessly and/or in a wired manner. In an example, the processor may be implemented as a programmable digital signal processor (DSP). In another example, the processor may be implemented via a cloud server that provides a cloud computing service.

In some implementations, the processor is integrated with the sensing apparatus (namely, a first processor). In such implementations, the processor is physically coupled to the sensing apparatus (for example, attached via mechanical and electrical connections). In other implementations, the processor is implemented separate from the sensing apparatus, integrated with a comprehensive system, either locally (namely, a second processor) or as a cloud-based platform (namely, a third processor).

Optionally, the at least one processor is implemented at least partially as a cloud-based processor communicably coupled to the sensing apparatus. In such embodiments, the sensing apparatus may include local processing circuitry for basic signal acquisition and pre-processing, while additional processing functions are performed remotely using one or more cloud computing resources accessible via a communication network. The sensing apparatus may transmit the first sensor data, the second sensor data, and/or the measurement data to the cloud-based processor through a wired or wireless communication interface, for example via a cellular communication module or other network connection. The cloud-based processor may then perform further processing, such as phase current reconstruction, fault detection and classification, event prediction, and correlation of data from multiple sensing apparatuses deployed across the electric utility grid. The technical advantage is that cloud-based implementation enables scalable and centralized computation, reduces processing burden and power consumption at the pole-mounted sensing apparatus, and improves the accuracy and reliability of grid monitoring by leveraging greater computational resources and aggregated measurement data.

It will be appreciated that the at least one processor is implemented at least partially as a cloud-based processor communicably coupled to the sensing apparatus, meaning that processing functionality is divided between a processing performed locally at or near the sensing apparatus and a processing performed remotely by one or more cloud computing resources accessed via a communication network. In one scenario, a first processor is located within the sensing apparatus and is configured to perform sensor interfacing and pre-processing, such as sampling, digitization, filtering, time-alignment, offset and gain correction, and generation of preliminary measurement data, and to transmit at least a portion of the first sensor data, the second sensor data and/or the measurement data via a communication module. In a further scenario, a second processor is implemented remotely, for example as a cloud-based processor, and is configured to receive the transmitted data and perform higher-level computation, such as reconstructing overhead line phase currents from multi-sensor measurements using calibration parameters, sensor directivity and orientation, and conductor geometry. In a further scenario, a third processor is implemented remotely (for example, as part of a cloud analytics service or grid management platform) and is configured to utilize reconstructed phase currents and associated measurement data to detect, classify, and locate events or faults, predict likely events or faults, and generate alerts or recommended actions for a network operator.

Accordingly, “at least partially” encompasses embodiments where the sensing apparatus performs only initial pre-processing and the cloud performs phase-current reconstruction and fault analytics, as well as embodiments where a portion of the phase-current reconstruction is performed locally and refined or validated in the cloud using aggregated data from multiple sensing apparatuses. The technical advantage is that distributing processing across local and cloud-based processors provides scalable computation and centralized analytics while reducing on-device computational load and power consumption, thereby improving the accuracy, responsiveness, and reliability of grid monitoring and fault management

Optionally, the processor is communicably coupled to a data repository. It will be appreciated that processing data are stored at the data repository. The data repository is optionally implemented as a memory. The memory may be local memory that is integrated with the processor, may be an external memory, may be a cloud-based memory, or similar.

The term “magnetic field density” refers to the amount of magnetic force induced in the circuit due to the magnetisation caused by current being transmitted through the electrical overhead lines. It will be appreciated that the magnetic field density of a given electrical overhead line is utilised to determine the value of current flowing through the given electrical overhead line. Optionally, the value of current flowing through the given electrical overhead line is determined using formulae. Referring to FIG. 6, a distance of the sensing apparatus from the electrical overhead line on the x axis is Lx, a distance of the sensing apparatus from the electrical overhead line on the y axis is Ly, and the approximate distance of the sensing apparatus from the electrical overhead line is L_{xy}.

Sensor signals of a given sensor device (i.e., the magnetic field sensor device) are mathematically represented as Hₘ=ΣIₙ*D_{m,n}/L_{m,n}.

$$( \begin{matrix}{H}_{x} \\ {H}_{y} \\ {H}_{z}\end{matrix} ) = ( \begin{matrix}{A}_{xa} & {A}_{xb} & {A}_{xc} \\ {A}_{ya} & {A}_{yb} & {A}_{yc} \\ {A}_{za} & {A}_{zb} & {A}_{zc}\end{matrix} ) ( \begin{matrix}{I}_{a} \\ {I}_{b} \\ {I}_{c}\end{matrix} )$$

such that, Aₘₙ=Dₘₙ/Lₙ.
   wherein:
H=magnetic field detected
m=given sensor device
n=index number of a wire of the electrical overhead line
I=current in the wire of the electrical overhead line
D=directional gain of the sensor device to the wire of the electrical overhead line; and
L=distance between the sensor device and the wire of the electrical overhead line.

The line currents of each three wires of the electrical overhead line can be calculated using the matrix equation above, when D and L of each wire/sensor pair are known. A technical effect of this is that the use of magnetic field sensors avoids direct connection of the sensing apparatus with the electrical overhead lines, which, in turn, makes the sensing apparatus economical, as well as allows the system to be utilised with pre-existing electric utility grids as well. Moreover, the sensing apparatus can be hot-installed (i.e., installed without turning the system off) behind safety distance, and also there are no cost for safety insulation between the mid- or high-voltage line and the sensing apparatus.

It will be appreciated that, in particular, each magnetic field sensor device may have a directional reception strength pattern or radiation pattern to determine the magnetic field density of the electrical overhead lines. As used herein, the term “reception strength pattern” or “radiation pattern” of a magnetic field sensor device refers to a directional characteristic indicating the relative sensitivity or response of the sensor device to incident magnetic fields from different spatial directions. The reception strength pattern may include one or more directions of relatively high sensitivity and at least one direction of reduced sensitivity.

Optionally, the magnetic field sensor device is implemented as a coil wound around a ferrite core, wherein the coil is made of a conducting material. Optionally, the conducting material is implemented as at least one of: copper, gold, silver, aluminium. Herein, the term “ferrite” refers to a ceramic material made by iron (III) oxide and at least one additional metallic element. Optionally, the additional metallic element is implemented as at least one of: strontium, barium, manganese, nickel, zinc. It will be appreciated that the ceramic material is ferrimagnetic, meaning thereby, that the ferrite core is magnetizable and/or be attracted to a magnet. Optionally, the ferrite core is made by heating the ceramic material and moulding it into a cylindrical shape. Optionally, the coil is made by stretching bits of the conducting material to form a wire. Optionally, a resonant frequency of the coil is higher than a Nyquist frequency of an input sampling frequency of an analog front end of the electric utility grid. A technical effect of this is that this configuration guarantees high gain in high frequencies, which in turn is beneficial for accurate detection of the current transient.

Alternatively, optionally, the magnetic field sensor device is implemented as an air-core coil. The term “air-core coil” refers to a coil wound around a non-magnetic core. Optionally, the air-core coil may be wound around a plastic, a ceramic, a glass, a chunk of fabric, a piece of wood, or even air. A technical advantage of this is that it is cheaper, is free from iron losses, resulting in less distortion.

Yet alternatively, optionally, the magnetic field sensor device is implemented as a hall-effect sensor. The term “hall-effect sensor” refers to a sensor which detects the presence and magnitude of a magnetic field using the Hall effect. In operation, the hall-effect sensor distinguishes between the positive and negative charge moving in opposite direction. Moreover, a magnetic field detected by the hall-effect sensor is converted to suitable analog or digital signals which can be read by the measurement device. Optionally, the hall-effect sensor is made using at least one of: gallium arsenide (GaAs), indium arsenide (InAs), indium phosphide (InP), indium antimonide (InSb), graphene. A technical advantage of this is that hall-effect sensors have reduced wear and tear due to absence of moving parts, which substantially reduces the maintenance costs.

Still alternatively, optionally, the magnetic field sensor device is implemented as a metal core sensor. The term “metal core sensor” refers to a magnetic field sensor having a metallic core and wound with fibre or ceramic coil. Optionally, the metal core sensor is an iron core sensor. A technical advantage of this is faster travel speeds and higher deposition rates, resulting in increased efficiency and reduced costs.

Optionally, the magnetic field sensor device is protected from the magnetic field emitted by the electrical overhead lines by a shield (or, cover, made of a high-permeability material) wherein an impact of low-voltage currents on the measurements of the overhead line currents is minimized. Optionally, a radiation pattern of the magnetic field sensor is adjusted to minimize impact on the shield by at least one of: the first processor, the second processor. Optionally, the sensing apparatus is arranged close to the electrical overhead lines to be measured. Optionally, the sensing apparatus is fixed on the electrical pole. Alternatively, optionally, the sensing apparatus is fixed on a pole in proximity to the electrical pole. Advantageously, the sensing apparatus is arranged on the electrical pole to provide security from thieves, as well as a secure installation location to avoid damage or disruption caused by natural elements including wind, rain, and the like. The cross-positioned two-sensor configuration is caused by the second sensor device overlapping with the first sensor device. Optionally, the cross-positioned configuration is such that the first sensor device is arranged horizontally, and the second sensor device is arranged vertically to a reference plane. Alternatively, optionally, the cross-positioned configuration is such that the first sensor device is arranged vertically, and the second sensor device is arranged horizontally to a reference plane. In such a configuration, magnetic fields of the crossed devices are not directly overlapping, allowing the sensor devices to detect electrical overhead line events and faults more accurately by gathering sensor data more efficiently. Moreover, the cross-positioned two-sensor configuration may be rotated in any direction, including but not limited to, north, north-east, north-west, east, west, south, south-east or south-west. Alternatively, optionally, the cross-positioned configuration is such that the first sensor device overlaps the second sensor device at an angle. Herein, the angle lies in a range of 15-75 degrees.

The third sensor device is arranged at the distance from the cross-positioned two-sensor configuration, such that more sensor data is recorded from different variations of the arrangement of the sensor devices.

A technical benefit of this is to improve measurement accuracy, measurement quality, and to provide a compact electronic device, due to crossed devices.

Optionally, the electrical overhead lines are configured with respect to the electrical pole in:
a horizontal arrangement;
a vertical arrangement;
a triangle arrangement; or
two alike circuits on top of each other.

An exemplary illustration of the horizontal configuration of the electrical overhead lines with respect to the electrical pole is shown in FIG. 4A. Moreover, an exemplary illustration of the vertical configuration of the electrical overhead lines with respect to the electrical pole is shown in FIG. 4B.

Optionally, when the electrical overhead lines are configured in the triangle arrangement, two electrical overhead lines are arranged horizontally, and one electrical overhead line is arranged vertically with respect to the two electrical overhead lines. Herein, when seen from a side perspective, the electric overhead lines appear to form a triangle.

Optionally, when the electrical overhead lines are configured as two alike circuits on top of each other, the conductors from the same feeder transmit electricity in same direction. For example, when the electrical overhead lines are configured as two horizontally circuits on top of each other, the conductors from the same feeder transmit electricity in same direction. A technical advantage of this is that the ambiguity of the signals from two or more circuits are resolved at the correlation phase when the non-correlating signal (which does not match topologically to the sensing apparatus) are simply ignored as they do not correlate.

Optionally, the arrangement of the sensing apparatus depends on a configuration of the electrical overhead lines with respect to the electrical pole, such that:
when the configuration of the electrical overhead lines with respect to the electrical pole is a horizontal configuration, the sensing apparatus is arranged vertically with respect to the electrical pole; and
when the configuration of the electrical overhead lines with respect to the electrical pole is a vertical configuration, the sensing apparatus is arranged horizontally with respect to the electrical pole, and/or shifted horizontally from the electrical pole.

Herein, the sensing apparatus is shifted horizontally with respect to a centre of the pole when the configuration of the electrical overhead lines with respect to the electrical pole is a vertical configuration or is not symmetrical with regard to the pole. Optionally, the sensing apparatus is installed using a mechanical support arrangement. Optionally, the sensing apparatus is arranged vertically with respect to the electrical pole, and when the configuration of the electrical overhead lines with respect to the electrical pole is a vertical configuration, the sensing apparatus is shifted horizontally with respect to the electrical pole. Beneficially, such a horizontal shift allows the sensor devices to measure the magnetic field with improved angular separation. A technical benefit of arranging the sensing apparatus based on the configuration of the electrical overhead lines with respect to the electrical pole is that the sensor devices are able to detect events of the electrical overhead lines with improved precision, when they are arranged in this manner based on the configuration of the electrical overhead lines. In operation, the sensing apparatus is arranged in proximity to the electrical overhead lines. A technical advantage of this is that it provides angular separation between the electrical overhead lines so that current in the electrical overhead lines can be distinguished from each other. Another technical advantage of this is that it provides higher magnetic fields which result in a better signal/noise ratio as compared to when the sensing apparatus is arranged at a distance from the electrical overhead lines, when current in the electrical overhead lines is low.

Alternatively, optionally, the sensing apparatus is arranged to be suspended from one or more of the electrical overhead lines. Optionally, the sensing apparatus is suspended from the one or more electrical overhead lines using a suspension tool. Optionally, the suspension tool is implemented as at least one of: a piece of wire, a ribbon, a cloth, a piece of plastic, a hook, an adhesive, a wire. A technical benefit of suspending the sensing apparatus from the electrical overhead lines is that the sensor devices of the sensing apparatus remain in close proximity to the electrical overhead lines, such that the sensing apparatus efficiently senses the magnetic field induced by the current in the electrical overhead lines.

Optionally, the sensing apparatus is powered by the electrical overhead lines. Herein, the sensing apparatus is connected to the electrical overhead lines in a galvanic manner, such that electricity is supplied to the sensing apparatus for functioning by the electrical overhead lines. A technical advantage of this is that additional sources of energy would not be required to power the sensing apparatus, and hence maintenance costs would be drastically reduced. Alternatively, optionally, the sensing apparatus is powered using a solar panel. Yet alternatively, optionally, the sensing apparatus is powered using batteries. Alternatively, the sensing apparatus is powered from nearby low-voltage electrical overhead lines.

Optionally, a shortest distance between the sensing apparatus and the electrical overhead lines lies in a range of 500 millimetres-2000 millimetres for distribution networks. The term “shortest distance” refers to the distance between a given electrical overhead line and the closest sensor device of the sensing apparatus. Herein, the sensing apparatus is optionally installed in proximity to the electrical overhead lines. However, often a distance is required to be maintained between the sensing apparatus and the electrical overhead lines, for better functionality of the sensing apparatus and for safety reasons. A technical benefit of this is that the shortest distance allows enough space between the sensing apparatus and the electrical overhead lines, that the sensor devices can accurately gather sensor data for generating precise measurement data. Distribution network refers to a portion of the electric utility grid which transmits electricity from substations to a consumer. For example, the shortest distance may be from 500, 520, 540, 570, 1000 or 1500 millimetres up to 570, 1000, 1300, 1600, 1900 or 2000 millimetres.

Alternatively, optionally, a shortest distance between the sensing apparatus and the electrical overhead lines lies in a range of 1000 millimetres-10000 millimetres for transmission networks. More optionally, the shortest distance between the sensing apparatus and the electrical overhead lines is over 1000 mm for higher voltage transmission networks. Transmission network refers to a portion of the electric utility grid transmitting bulk electricity from a generation site over long distances to substations. For example, the shortest distance may be from 1000, 1200, 1300, 1500, 1700, 2100, 2500, 3000, 4000 or 5000 millimetres up to 2500, 3000, 4000, 6000, 8000 or 10000 millimetres.

Optionally, the sensing apparatus comprises at least one magnetic noise source along with the magnetic field sensor. In this regard, at least one magnetic noise source along with the magnetic field sensor are enclosed within a housing (defined later) or located outside the housing. The term “magnetic noise source” refers to any component or circuit located within the housing or outside the housing that, during operation, generates electromagnetic emissions capable of coupling into the magnetic field sensor devices, such as a switched-mode power supply, direct current-direct current (DC-DC) converter, battery charging circuitry, processor clock circuitry, radio-frequency transmitter, cellular communication module, wireless communication circuit, a neutral wire, a ground wire, a low-voltage line, communications cabling, and wires of another distribution line or transmission line.

Each magnetic field sensor device may have a directional sensitivity characteristic such that its response to magnetic fields varies with direction and includes at least one direction of reduced response, referred to herein as a ‘direction of minimum magnetic field sensitivity’ (also termed a pickup minimum direction). The term “direction of minimum magnetic sensitivity” refers to a spatial direction relative to a magnetic field sensor device in which the sensor exhibits its lowest response to an incident magnetic field. In other words, it is a direction along which a magnetic field produces a minimum induced signal, minimum output voltage, minimum induced current, or minimum measurable response from the magnetic field sensor device. For example, in a coil-based magnetic field sensor, the direction of minimum magnetic sensitivity may correspond to an axis substantially parallel to the longitudinal axis of the coil, along which the magnetic flux linkage through the coil windings is minimized. In other types of magnetic sensors, such as Hall-effect or magnetoresistive sensors, the direction of minimum magnetic field sensitivity may correspond to an orientation relative to the sensing plane or sensing axis in which the sensor output is minimized due to its inherent directional response characteristics. Accordingly, the direction of minimum magnetic field sensitivity represents a directional null or reduced-response axis of the magnetic field sensor device and may be determined based on the structural configuration and sensing principle of the sensor. Additionally, each magnetic field sensor device is arranged with respect to the magnetic noise source (internal or external) least one pickup minimum direction and may be positioned such that the pickup minimum direction is aligned toward the magnetic noise source (internal or external). This reduces coupling of emissions into the sensor measurement path while maintaining sensitivity to magnetic fields generated by external overhead line conductors.

The direction of minimum magnetic field sensitivity of the magnetic field sensor device may be determined based on manufacturer specifications of the sensor device, by empirical calibration, by measuring sensor output in response to a controlled magnetic field applied from different directions, or by computational modeling of the sensor geometry.

In an embodiment, the magnetic field sensor device is mechanically oriented during assembly such that the direction of minimum magnetic field sensitivity is aligned toward a predetermined magnetic noise source.

In another embodiment, the orientation is determined during installation by measuring magnetic interference from one or more magnetic noise sources and rotating the magnetic field sensor device to minimize interference amplitude.

In such embodiments, the magnetic field sensor devices are physically mounted within the housing (for example, on a printed circuit board, sensor bracket, or internal support frame) with a selected orientation relative to the magnetic noise source (internal or external) such that the direction of minimum magnetic sensitivity of each magnetic field sensor device is aligned toward the magnetic noise source. This alignment reduces coupling of internally or externally generated electromagnetic interference into the sensing axis of the magnetic field sensor devices while the magnetic field sensor devices remain oriented to sense magnetic fields produced by electrical currents flowing through external overhead line conductors. The orientation may be determined during design or installation by identifying the dominant electromagnetic noise source within the housing and aligning the sensor device such that its minimum-sensitivity axis points toward the identified noise source, thereby improving signal-to-noise ratio and measurement fidelity for subsequent current reconstruction and fault detection.

Optionally, the magnetic noise source comprises at least one of: a switched-mode power supply, a current converter, a radio-frequency transmitter, a cellular communication module, a wireless communication circuit. Herein, the switched-mode power supply is a power supply that regulates and converts power by rapidly switching electronic components on and off at high frequency, which can generate switching transients and electromagnetic emissions. The current converter is a power conversion circuit (for example, a DC-DC converter, rectifier, or inverter) that converts and/or regulates current and voltage to supply power to components, can likewise generate switching noise and electromagnetic emissions during operation. The switched-mode power supply or current converter operates by rapidly switching electrical currents to regulate voltage, which generates magnetic leakage fields, harmonics, and high-frequency transients. Similarly, a radio-frequency transmitter, cellular communication module, or wireless communication circuit generates electromagnetic fields during wireless data transmission. In compact pole-mounted sensing apparatuses, such components are often positioned near the magnetic field sensor devices due to space constraints, and their emissions may introduce interference into the sensor measurement path. Accordingly, identifying these components as magnetic noise sources enables the sensing apparatus to reduce such interference, for example by orienting magnetic field sensor devices such that their directions of minimum magnetic sensitivity are aligned toward the magnetic noise source (internal or external), thereby improving measurement fidelity and fault monitoring accuracy. The technical advantage is that by identifying and accounting for such components as internal, or external, magnetic noise sources, the sensing apparatus can reduce generated interference, for example by orienting the magnetic field sensor devices such that their directions of minimum magnetic sensitivity are aligned toward the magnetic noise source, thereby improving signal-to-noise ratio, measurement accuracy, and reliability of fault detection in the electric utility grid.

It will be appreciated that the noise-minimizing orientation embodiments (i.e., inclusion of a magnetic noise source and aligning the magnetic field sensors relative to their directions of minimum magnetic sensitivity) described herein apply, mutatis mutandis, to apparatus, system, and method embodiments of the present disclosure, including embodiments for installation, monitoring, current reconstruction, and fault management in electric utility grids.

Optionally, the housing enclosing the sensing apparatus is implemented as one of: an integrated housing, a distributed housing. The housing encloses one or more magnetic field sensor devices and one or more electronic subsystems required for operation of the sensing apparatus. For example, the housing may be a weatherproof pole-mounted enclosure. The housing is utilised as a protective layer for safeguarding components of the sensing apparatus from excessive wear and tear caused by natural elements, and/or damage. Moreover, the integrated housing refers to when all components of the sensing apparatus are installed in the same housing, and the distributed housing is when components of the sensing apparatus are divided in two or more separate housings. For example, if the sensing apparatus is enclosed in the distributed housing, the first sensor device, the second sensor device and the third sensor device may be arranged in a first housing and the first processor may be arranged in a second housing. A technical advantage of this is that it allows the sensing apparatus to be installed in any of the two housings, depending on the space and weather conditions, and the electrical overhead line configuration at a given location of installation.

Optionally, when the housing is the distributed housing, the at least one magnetic field sensor device, and the at least one magnetic noise source second sensor device are arranged in proximity to the electrical pole. In such embodiments, at least one magnetic field sensor device, and optionally additional magnetic field sensor devices including a first sensor device, a second sensor device and a third sensor device, are arranged in proximity to the electrical pole to remain sufficiently close to the electrical overhead lines for accurate magnetic field sensing. Moreover, in compact pole-mounted implementations, at least one magnetic noise source (internal or external) (for example, power conversion, processing, or wireless communication circuitry) may be located within an enclosure portion positioned in proximity to the electrical pole. In such configurations, the sensor devices may be oriented relative to the magnetic noise source, for example by aligning a direction of minimum magnetic field sensitivity of each sensor device toward the magnetic noise source, to reduce electromagnetic interference while maintaining sensitivity to magnetic fields generated by the electrical overhead lines. This distributed housing arrangement enables compact pole-mounted installation while keeping the magnetic field sensor devices close enough to the overhead conductors for accurate current measurement, and reduces generated electromagnetic interference (EMI) from nearby electronics or electrical systems by orienting each sensor's minimum-sensitivity direction toward the magnetic noise source, thereby improving signal-to-noise ratio and the reliability of phase-current reconstruction and fault detection without increasing enclosure size or relying on bulky shielding.

Optionally, when the housing is the distributed housing, the first sensor device, the second sensor device and the third sensor device are arranged in proximity to the electrical pole. Depending on the configuration of the electrical overhead line configuration, the configuration of the sensing apparatus may either be vertical or horizontal. A vertical configuration for the distributed housing of the sensing apparatus is shown in FIG. 4A, such that the third sensor device is arranged vertically to the cross-positioned two-sensor configuration. Optionally, when the sensing apparatus is arranged horizontally with respect to the electrical pole, the sensing apparatus may be housed in the distributed housing and installed around the electrical pole at the predetermined height. Moreover, a horizontal configuration for the distributed housing of the sensing apparatus is shown in FIG. 4B. As shown, the sensor devices are arranged near a base of the electrical pole. Optionally, if the sensing apparatus comprises additional sensor devices (such as a fourth sensor device, a fifth sensor device, and so on), the additional sensor devices are also placed in proximity to the pole.

Optionally, the second processor and the third processor are comprised in the sensing apparatus. Herein, in some cases, the second processor and the third processor are physically installed in the housing of the sensing apparatus. In other cases, the second processor and the third processor are remotely installed and are communicably coupled to the first processor in a wired or wireless manner.

Alternatively, optionally, the second processor and the third processor are comprised in the system for monitoring and managing events and faults in an electric utility grid. Herein, the second processor and the third processor are installed at a location of the system. Optionally, the second processor and the third processor are installed at a server of the system. Optionally, the second processor and the third processor act as servers for the system.

The term “overhead line phase current” refers to current flowing through one phase of the electrical overhead lines. The measured value of the current flowing through the electrical overhead lines are utilised for calculating the overhead line phase current. It will be appreciated that reproducing the overhead line phase current assists in locating the event or fault in the electric utility grid. Furthermore, it will be appreciated that reproducing the overhead line phase current assists in identifying current transients and locating the event or fault in the electric utility grid.

Moreover, the measurement data and the sensor data are examined to identify events and faults in the electric utility grid. Optionally, the measurement data and the sensor data are examined using a data processing algorithm. Herein, the data processing algorithm identifies events and faults by finding the current transients in the measurement data.

Optionally, the sensing apparatus further comprises a fourth sensor device, wherein the fourth sensor device is arranged to overlap the third sensor device to form another cross-positioned two-sensor configuration and arranged at the distance from the cross-positioned two-sensor configuration. Notably, often the electrical overhead lines have four lines, of which one is a ground wire, while the other three carry phase currents. Beneficially, in such cases, the fourth sensor device measures a current flowing through the ground wire. A technical advantage of the fourth sensor device is that it enables precise measurement of the current by providing values of the current flowing through the ground wire. Optionally, a current transformer is utilized with the fourth sensor device to measure the current flowing through the ground wire. It will be appreciated that the fourth sensor device is a ground-wire current sensor used to measure current through ground wire. Optionally, the processor detects the ground current based on the measured ground-wire current, i.e., to detect ground faults in the electrical overhead lines and generate a second sensor data. Herein, the term “ground-wire current sensor” refers to a sensing device configured to detect electrical current flowing through a ground wire or neutral conductor associated with the electrical overhead lines. The ground-wire current sensor may be implemented, for example, as a current transformer arranged around the ground or neutral conductor, a magnetic field sensor positioned adjacent to the conductor, a Rogowski coil, or another non-intrusive current sensing element capable of measuring current without requiring galvanic interruption of the conductor. In operation, current flowing through the ground or neutral conductor produces a magnetic field that induces a measurable signal in the ground-wire current sensor, which is converted into electrical output signals representative of the magnitude and/or temporal characteristics of the ground or neutral current. The term “second sensor data” refers to data generated by the ground-wire current sensor that is indicative of current flowing through the ground or neutral conductor, and may include raw induced signal values, processed current magnitude values, time-varying waveform information, transient signatures, or derived parameters associated with ground fault conditions. The second sensor data may be processed together with first sensor data generated by one or more magnetic field sensor devices sensing phase conductors, thereby enabling differentiation between phase currents and ground currents. This provides the technical advantage of improving detection and localization of ground faults, high-impedance faults, and asymmetrical fault conditions, enhancing overall fault discrimination accuracy and reliability in electric utility grid monitoring systems, while allowing safe, non-intrusive pole-mounted installation.

Optionally, the ground-wire current sensor is arranged on or around a ground wire of the electric utility grid or a neutral wire from amongst the electrical overhead lines. In this regard, the ground-wire current sensor is arranged on or around a ground wire of the electric utility grid or a neutral wire from amongst the electrical overhead lines, for example by placing a current transformer, Rogowski coil, or clamp-on sensing element around the ground or neutral conductor such that magnetic fields generated by current in the conductor induce a measurable sensor output. In operation, the ground or neutral conductor may carry return currents and/or fault currents (for example, during ground faults or asymmetrical fault conditions), and the ground-wire current sensor generates second sensor data indicative of such current. This arrangement provides the technical advantage of directly capturing ground or neutral current components that may not be reliably inferred from phase-conductor sensing alone, thereby improving fault discrimination and enhancing the accuracy and reliability of detecting and localizing ground faults, including high-impedance faults, while maintaining a non-intrusive pole-mounted installation.

It will be appreciated that at least one processor (namely, the first processor, and/or the second processor and/or the third processor) communicably coupled, for example, via wired connections and/or a local communication bus, to the at least one magnetic field sensor device and the ground-wire current sensor. The processor is configured to receive first sensor data from the magnetic field sensor device and second sensor data from the ground-wire current sensor and to pre-process such data to generate measurement data. The pre-processing may include, for example, digitization, filtering, time-alignment, offset and gain correction, noise suppression, and/or normalization, such that the measurement data comprises values representative of magnetic field produced by electrical currents flowing through the electrical overhead lines and, where applicable, ground, or neutral current contributions. The processor is further configured to utilize the measurement data together with the first sensor data and the second sensor data to reproduce overhead line phase currents, for example by applying calibration parameters and solving relationships between sensor responses and conductor currents based on sensor directivity, orientation, and conductor geometry. The reproduced overhead line phase currents may then be used to detect and manage currents, events, and faults in the electric utility grid, including identifying current transients, classifying fault conditions, and supporting fault localization.

Optionally, the sensing apparatus further comprises a geolocation device, wherein the geolocation device provides location information of the sensing apparatus and timing information of the measurement data of the sensing apparatus. The term “geolocation device” refers to a device which utilises location technology to provide location data of the sensing apparatus. Optionally, the geolocation device utilises a satellite-based radionavigation system. Moreover, when the sensing apparatus processes the measurement data, the geolocation device tags the measurement data with the location information and the timing information. Optionally, the measurement data further comprises the location information and the timing information. The location information is advantageous in locating events and faults in the electric utility grid, and the timing information assists in timely tracking the events and faults in the electric utility grid by comparing the location information and timing information with a current propagation speed (i.e., an electrical current propagation speed) in the electrical overhead lines.

The present disclosure also relates to a method for reducing electromagnetic interference in a sensing apparatus installed on an electrical pole of an electric utility grid. Various embodiments and variants disclosed above, with respect to the aforementioned first aspect, apply mutatis mutandis to the method.

In this regard, the step of identifying a magnetic noise source located within a housing of the sensing apparatus, or located externally from the housing of the sensing apparatus, comprises determining which internal subsystem (such as a switched-mode power supply, current converter, processor clock circuitry, or wireless communication module) or external system (such as a neutral wire, a ground wire, a low-voltage line, communications cabling, and wires of another distribution line or transmission line) produces dominant electromagnetic emissions within the enclosure based on circuit layout, operating characteristics, and/or calibration measurements and based on the dominant electromagnetic emissions, the position or location of the magnetic noise source can be identified. The determination of a direction of minimum magnetic field sensitivity of at least one magnetic field sensor is performed based on manufacturer specifications, known sensor geometry, and/or a calibration procedure in which the sensor output is observed while varying sensor orientation relative to a reference magnetic field to identify a directional null or reduced-response axis. The magnetic field sensor is then oriented within the housing, for example by mounting the sensor on a circuit board, bracket, or internal support structure at a selected angular orientation, such that the direction of minimum magnetic field sensitivity is aligned toward the identified magnetic noise source, thereby reducing magnetic coupling of generated emissions into the sensor measurement path without requiring increased enclosure size or bulky shielding. The method further comprises sensing magnetic fields generated by electrical overhead lines while reducing electromagnetic interference from the magnetic noise source, such that the resulting sensor data more accurately represents external magnetic fields produced by overhead line currents and may be used with improved signal-to-noise ratio for current reconstruction and reliable detection, classification, and localization of events and faults in the electric utility grid.

The present disclosure also relates to the method for installing a sensing apparatus in an electric utility grid as described above. Various embodiments and variants disclosed above, with respect to the aforementioned first aspect and the second aspect, apply mutatis mutandis to the method.

Optionally, the information regarding the configuration of electrical overhead lines is at least one of:
pre-known, such that it is obtained from a data repository communicably coupled to the sensing apparatus;
obtained by conducting a survey of the electrical overhead lines.

Optionally, the pre-known information is collected by at least one of: a survey conducted in the past, a survey conducted while installing, images of the configuration of electrical overhead lines, satellite data collected pertaining to the configuration of electrical overhead lines. Optionally, the data repository is installed at the server of the system. Alternatively, optionally, the data repository is located remotely and is communicably coupled in a wired or wireless manner with the sensing apparatus.

Moreover, the survey of the electrical overhead lines is conducted in at least one of: a manual manner, a digital manner. The manual survey requires a person to travel to a given location of the electric utility grid to gather the information regarding the configuration of electrical overhead lines. For example, the information regarding the configuration of electrical overhead lines may be manually surveyed when an installation team installed the sensing apparatus by using a measure, a photograph, or from line cross-arm manufacturer specifications. The digital survey allows persons living in a vicinity or travelling by the given location of the electric utility grid to provide the information regarding the configuration of electrical overhead lines. Optionally, a computer is utilized to conduct the digital survey of the electrical overhead lines. For example, the information regarding the configuration of electrical overhead lines may be digitally surveyed by the computer using photographs available on internet.

The present disclosure also relates to the system for reducing electromagnetic interference in a sensing apparatus installed on an electrical pole of an electric utility grid and for monitoring and managing events and faults in an electric utility grid, as described above. Various embodiments and variants disclosed above, with respect to the aforementioned first aspect, the second aspect and the third aspect, apply mutatis mutandis to the system.

The present disclosure also relates to the system for monitoring and managing events and faults in an electric utility grid as described above. Various embodiments and variants disclosed above, with respect to the aforementioned first aspect, second aspect, third aspect and fourth aspect apply mutatis mutandis to the system.

Optionally, the sensing apparatus further comprises a geolocation device, wherein the geolocation device provides location information of the sensing apparatus and timing information of the measurement data.

Optionally, the at least one third processor alerts the network operator by sending a notification pertaining to the detected or predicted event or fault and its location to the network operator. Optionally, the at least one third processor is further configured to send the notification at a device associated with the network operator. Optionally, the network operator is at least one of: a person, a vehicle, a robot, a maintenance drone, a company.

Optionally, when processing the measurement data, the at least one third processor is configured to:
detect a current transient, based on the measurement data, wherein the current transient indicates that the event or fault has occurred in the electric utility grid;
determine a first location and a first time instant at which the current transient occurs, based on the location information and the timing information, respectively; and
determine a second location of the current transient at a second time instant, based on at least on the first location, the first time instant, and a pre-known current propagation speed in the electrical overhead lines, wherein the second time instant is later than the first time instant.

To enhance accuracy and speed of fault location within an electric utility grid, the sensing apparatuses and associated systems may implement traveling wave fault location. Traveling wave fault location utilizes high-frequency transient signals, traveling waves, generated at the initiation of a fault, including a short circuit fault or a ground fault, wherein the high-frequency transient signals propagate along the electrical overhead lines at a predefined propagation speed associated with a line or cable segment.

In such embodiments, each sensing apparatus detects an arrival of the high-frequency transient signal and generates a time stamped data record associated with the arrival, including sensor data sampled around a fault event transient. Fault location is determined by processing a difference between arrival times measured by two or more spatially separated sensing apparatuses, wherein the difference between the arrival times corresponds to a distance along the electrical overhead lines based on the predefined propagation speed.

Accurate traveling wave fault location relies on precise time stamping of the time stamped data records across multiple sensing apparatuses. In such embodiments, each sensing apparatus includes a clock synchronized using an external time reference. The external time reference may be derived from a global navigation satellite system (GNSS), including GPS or Galileo, or from a terrestrial timing network. The synchronized clock enables time stamping of sensor data and measurement data with microsecond-level accuracy or nanosecond-level accuracy, thereby enabling determination of minimal time differences between arrivals of the high-frequency transient signals at different sensing apparatuses and improving fault location accuracy.

Optionally, the current transient is detected by utilising detection algorithms. The current transient is noticeable as a sudden spike or plummet in the measurement data. Optionally, the current transient is detected by utilising data processing algorithms trained to identify the current transient by analysing the measurement data. It will be appreciated that the measurement data generated by each sensing apparatus is stamped with the location and timing information, such that checking the location information and the timing information at which the current transient occurs provides the first location and the first time instant (i.e., a first time stamp). Moreover, the current propagation speed and a current propagation direction is utilised to predict the second location of the current transient. Measurement data generated by a sensing apparatus at the second location is studied to determine the presence of the current transient. Since the current transient occurs at the second location after occurring at the first location, the second time instant is later than the first time instant. A technical effect of this is the timely detection of the event or fault, along with determining where and when the event or fault can be fixed (the second location, the second time instant). This determination of the second processor saves time and minimises requirement of manual intervention, which in turn prevents complete grid failure by timely addressing events and faults.

Optionally, prior to processing the measurement data, the at least one second processor is further configured to derive characteristics of waveforms of current transients in different feeder networks by modelling dynamics of the different feeder networks, and wherein the current transient is detected when characteristics of samples in the measurement data are similar to one of the derived characteristics.

Optionally, the pre-known current propagation speed in the electrical grid is selected by a user of the system. Alternatively, optionally, the pre-known current propagation speed is measured to check the value of the pre-known current propagation speed. Herein, measurement data received from a plurality of sensing apparatuses is utilised to measure the pre-known current propagation speed, optionally by a fourth processor which is configured to calculate the pre-known current propagation speed from the time instant of the measurement data, correlating the measurement data sent by the first processor and mapping the time instant network topology information (i.e., information pertaining to the configuration of the electrical overhead lines) to calculate the pre-known current propagation speed in the electric utility grid, optionally using a stimulus event of known location (such as, a trip-on or a reconnect), at a substation in the electrical grid. Moreover, an approximate electrical overhead line length is calculated by measuring time taken by an electrical current transient to travel from one pole (and thereby, a sensing apparatus) to another, and assuming generic values for the pre-known current propagation speed therein.

Optionally, the at least one sensing apparatus comprises a plurality of sensing apparatuses, and wherein the second location of the current transient at the second time instant is determined based also on at least one of:
a correlation between measurement data received from the plurality of sensing apparatuses, said correlation taking into account at least the pre-known current propagation speed and timing information received from the plurality of sensing apparatuses;
characteristics of samples in the measurement data.

Herein, each sensing apparatus is installed at an electrical pole of the electric utility grid. Alternatively, optionally, each sensing apparatus is installed on the electrical overhead lines of the electric utility grid. Herein, each sensing apparatus is optionally installed using current transformer type of sensors. Since the measurement data is being generated by each of the plurality of sensing apparatuses, the measurement data is correlated to determine the second time instant. Optionally, the correlation is performed using a correlation algorithm. Moreover, the characteristics of samples in the measurement data are studied to understand which events and faults are related to a given current transient. This is beneficial since it provides added insight and enables an efficient determination of the second time instant.

A technical benefit of using multiple sensing apparatus and correlating their respective data is that correlation of the data enhances accuracy of the system (mainly for the steps of detection/prediction). Optionally, the at least one second processor is further configured to send, to an electric utility management system, the second location of the current transient at the second time instant, wherein the electric utility management system, in operation, performs automatic fault isolation in the electric utility grid. Herein, the automatic fault isolation is performed by isolating the fault such that it does not cause damage to the entire electric utility grid. Optionally, using the characteristics of samples in the measurement data as a basis enhances the accuracy of the correlation.

Optionally, when processing the measurement data, the location information, and the timing information, the at least one third processor is configured to:
detect at least one fault precursor event, based at least on the measurement data; and
employ at least one of: a statistical algorithm, a machine learning algorithm, to predict when and where the fault is likely to occur in the electric utility grid, based on the at least one fault precursor event.

The term “fault precursor event” refers to an event which acts as a precursor to a fault. The fault precursor event is implemented as at least one of: a power quality issue (caused by excess harmonics), a rapid load change, an interruption, an induced lighting strike, excessive non-linear switching of power loads causing resonant pulses in the medium voltage network, an asymmetrical load, a partial discharge, a sparking, an arc. For example, a slight irregularity in the current transmitted through the electrical overhead lines. Optionally, the detection of the at least one fault precursor event is based also on at least one of: weather information pertaining to the electric utility grid, geographical information pertaining to the electric utility grid, electric utility grid parameters (for ex. load information). A technical effect of this is that such prediction based on fault precursor events prevents grid failure by timely predicting when and where a fault is likely to happen. Optionally, the at least one second processor is further configured to generate a statistical representation and/or a fault report, based on the measurement data, the location information, and the timing information.

Prediction algorithms implemented as at least one of: the statistical algorithm, the machine learning algorithm are employed to predict when and where the fault is likely to occur in the electric utility grid. Examples of a prediction algorithm include, but are not limited to, a regression algorithm, a pattern recognition algorithm, a data extrapolation algorithm, a linear regression algorithm, a random forest algorithm, a gradient boost algorithm, a utilization of neural networks algorithm.

Optionally, the at least one third processor is further configured to:
determine at least one maintenance task that is to be performed for the electric utility grid, based on: the fault that has occurred in the electric utility grid and/or the fault that is likely to occur in the electric utility grid; and
send a notification to at least one device associated with at least one maintenance entity, wherein the notification is indicative of at least one maintenance task to be performed.

The term “maintenance task” refers to an action that is to be performed for the system for monitoring and managing faults in an electric utility grid, in order to monitor and manage the faults. Optionally, the at least one maintenance task is predicted further based at least on: a type of the electric utility grid, the location of the electric utility grid, weather conditions in a vicinity of the electric utility grid. Optionally, the at least one maintenance task is at least one of: repairing a fault in the electric utility grid, repairing a damage in the electric utility grid which may lead to a fault, general maintenance of checking the condition of the electrical overhead lines, electrical pole or sensing apparatus. For example, the at least one maintenance task may be removal of a fallen tree from the electrical overhead lines. Optionally, for the faults that are likely to occur, when the at least one maintenance task is to be performed is also determined. When the at least one maintenance task is to be performed pertains to at least one of: a time at which the at least one maintenance task is to be performed, a date at which the at least one maintenance task is to be performed, a frequency at which the at least one maintenance task is to be performed. In this regard, the time, the date, and/or the frequency, at which the at least one maintenance task is to be performed may be predicted as a future time instant, a future date, a time interval, a time frequency, and the like. For example, it may be predicted that the general maintenance check for electrical pole number 23456 should be performed every 8 weeks.

Optionally, the at least one maintenance entity is at least one of: a maintenance person, a maintenance vehicle, a maintenance robot, a maintenance drone, a maintenance company. Optionally, the at least one third processor is further configured to send the notification at the device associated with at least one of: a maintenance person, a maintenance robot, a maintenance drone, wherein the notification pertains to the at least one maintenance task to be performed. In operation, the notification is provided at the device prior to the predicted instance of when the at least one maintenance task is to be performed. The notification has information pertaining to a given maintenance task to be performed. The notification includes at least one of: a maintenance task to be performed, a type of maintenance task to be performed, when the maintenance task is to be performed, a location at which the maintenance task is to be performed, a product number for which the maintenance task is to be performed. For example, the notification may alert a technical support executive to check on irregular voltages in Oklahoma. Optionally, the notification is indicative also of: a manner in which the at least one maintenance task is to be performed, when the at least one maintenance task is to be performed, and the like.

A technical effect of this is that the second processor determines which task is to be performed based on the occurrence of fault/prediction of fault, where the task is to be performed, and when it is to be performed and sends a requisite notification to a maintenance entity, which saves time and is efficient in managing resources.

The present disclosure also relates to the method for monitoring and managing events and faults in an electric utility grid as described above. Various embodiments and variants disclosed above, with respect to the aforementioned first aspect, second aspect and third aspect, apply mutatis mutandis to the method.

Optionally, the method further comprises receiving from a geolocation device of the at least one sensing apparatus, location information of the sensing apparatus and timing information of the measurement data.

Optionally, when processing the measurement data, the method further comprises:
detecting a current transient, based on the measurement data, wherein the current transient indicates that the event or fault has occurred in the electric utility grid;
determining a first location and a first time instant at which the current transient occurs, based on the location information and the timing information, respectively; and
determining a second location of the current transient at a second time instant, based on at least on the first location, the first time instant, and a pre-known current propagation speed in the electrical overhead lines, wherein the second time instant is later than the first time instant.

Optionally, when the at least one sensing apparatus comprises a plurality of sensing apparatuses, the second location of the current transient at the second time instant is determined based also on at least one of:
a correlation between measurement data received from the plurality of sensing apparatuses, said correlation taking into account at least the pre-known current propagation speed and timing information received from the plurality of sensing apparatuses;
characteristics of samples in the measurement data.

Optionally, when processing the measurement data, the location information, and the timing information, the method further comprises:
detecting at least one fault precursor event, based at least on the measurement data; and
employing at least one of: a statistical algorithm, a machine learning algorithm, to predict when and where the fault is likely to occur in the electric utility grid, based on the at least one fault precursor event.

Optionally, the method further comprises:
determining at least one maintenance task that is to be performed for the electric utility grid, based on the fault that has occurred in the electric utility grid and/or the fault that is likely to occur in the electric utility grid; and
sending a notification to at least one device associated with at least one maintenance entity, wherein the notification is indicative of at least the at least one maintenance task to be performed.

### EXPERIMENTAL PART

A test simulation for evaluating beneficial sensor device arrangements in the sensing apparatus was performed. It was observed that a single sensor device can only sense presence and magnitude of a magnetic field in a given plane, which did not accurately identify the presence and magnitude of the magnetic field (i.e., the magnetic field density) of the given electrical overhead line. Notably, the value of current flowing through the given electrical overhead line is representative of the magnetic field density of the given electrical overhead line, and vice versa. Since the magnetic field exists in all planes, it was observed that a plurality of sensor devices arranged in different directions accurately sensed the magnetic field density (which could then be easily utilized to determine the value of current flowing through the given electrical overhead line).

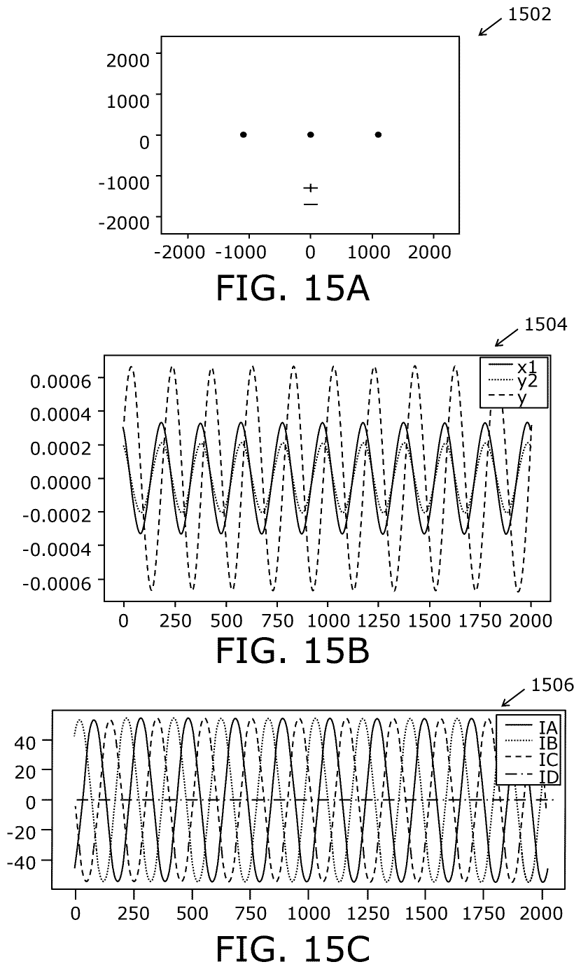

Moreover, it was observed that having two sensor devices overlap each other to form the cross-positioned two-sensor configuration was extremely beneficial since the magnetic fields did not overlap (i.e., since the sensor devices are positioned to be in different directions), such that precise values of the magnetic field are sensed. An exemplary sensor arrangement is shown in FIG. 15A, with representative sensor signals shown in FIG. 15B and calculated phase currents shown in FIG. 15C. It can be clearly observed how such sensor arrangement beneficially measures the phase currents of the electrical overhead lines.

Furthermore, it was observed that arranging the sensing apparatus with respect to the configuration of the electrical overhead lines beneficially enables the sensor devices to detect events of the electrical overhead lines with improved precision. Two exemplary arrangements of the sensor device with respect to the configuration of the electrical overhead lines are shown in FIGS. 4A and 4B. Moreover, it was observed that a number of sensor devices used in a given sensing apparatus when chosen in congruence with a number of electrical overhead lines (generally, there are three electrical overhead lines, so a three-sensor device arrangement provides precise results, however, in some areas there are four electrical overhead lines as well).

### DETAILED DESCRIPTION OF THE DRAWINGS

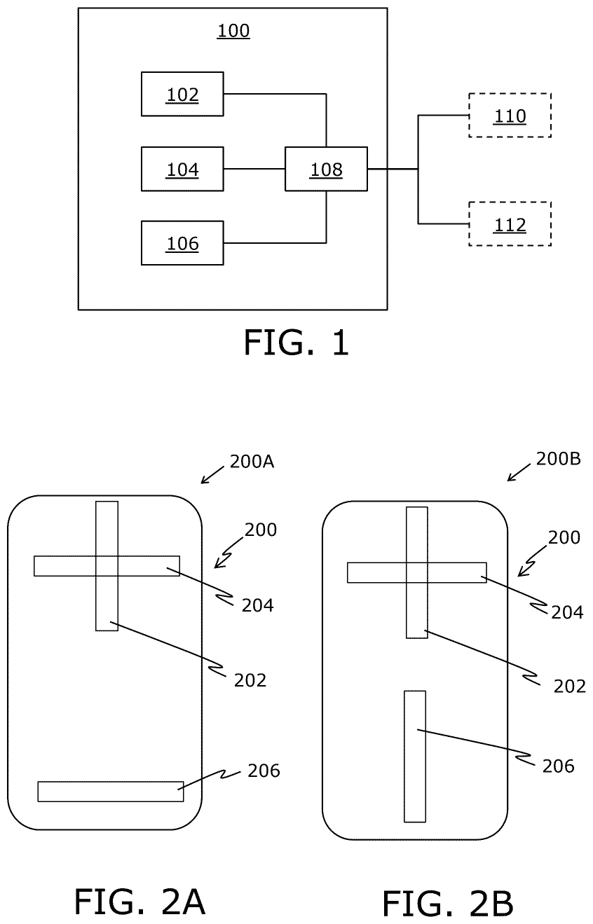

Referring to FIG. 1, illustrated is a block diagram of an architecture of a sensing apparatus 100, in accordance with an embodiment of the present disclosure. The sensing apparatus 100 comprises a first sensor device 102, a second sensor device 104, and a third sensor device 106. The sensing apparatus 100 further comprises a first processor 108. The first processor 108 is communicably coupled to the first sensor device 102, the second sensor device 104, and the third sensor device 106. Moreover, a second processor 110 and a third processor 112 are communicably coupled to the first processor 108.

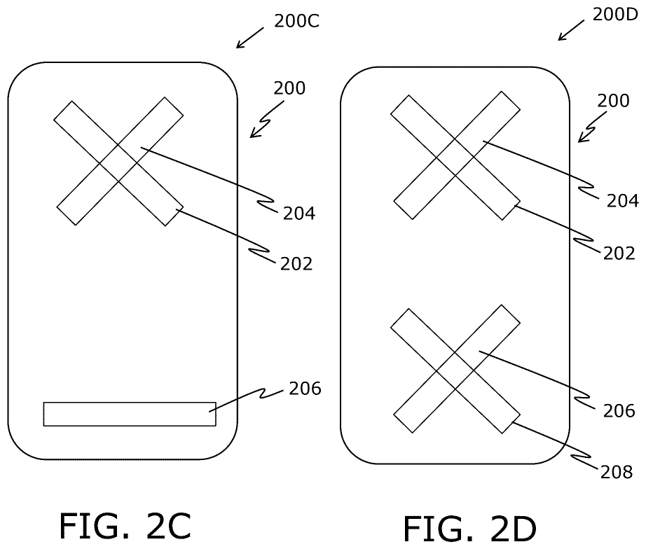

Referring to FIGS. 2A and 2B, illustrated are arrangements of sensor devices 202, 204, 206 in a sensing apparatus 200, in accordance with different embodiments of the present disclosure. The sensing apparatus 200 comprises a first sensor device 202, a second sensor device 204, and a third sensor device 206. The sensor devices 202, 204, 206, in operation, sense magnetic field in close proximity to electrical overhead lines of an electric utility grid to generate sensor data. The second sensor device 204 overlaps with the first sensor device 202 to form a cross-positioned two-sensor configuration. The third sensor device 206 is arranged at a distance from the cross-positioned two-sensor configuration.

Referring to FIG. 2A, illustrated is an arrangement 200A of sensor devices in a sensing apparatus 200, in accordance with an embodiment of the present disclosure. Herein, the third sensor device 206 is arranged horizontally with respect to the cross-positioned two-sensor configuration.

Referring to FIG. 2B, illustrated is an arrangement 200B of sensor devices in a sensing apparatus 200, in accordance with another embodiment of the present disclosure. Herein, the third sensor 206 is arranged vertically with respect to the cross-positioned two-sensor configuration.

Referring to FIG. 2C, illustrated is an arrangement 200C of sensor devices in a sensing apparatus 200, in accordance with another embodiment of the present disclosure. Herein, the cross-positioned two-sensor configuration formed by the first sensor device 202 and the first sensor device 204 is in shape of “X”. Moreover, the third sensor device 206 is arranged horizontally with respect to the cross-positioned two-sensor configuration.

Referring to FIG. 2D, illustrated is an arrangement 200D of sensor devices in a sensing apparatus 200, in accordance with another embodiment of the present disclosure. The sensing apparatus 200 further comprises a fourth sensor device 208. Herein, the cross-positioned two-sensor configuration formed by the first sensor device 202 and the first sensor device 204 is in shape of “X”. Moreover, the fourth sensor device 208 overlaps with the third sensor device 206 to form another cross-positioned two-sensor configuration in shape of “X”.

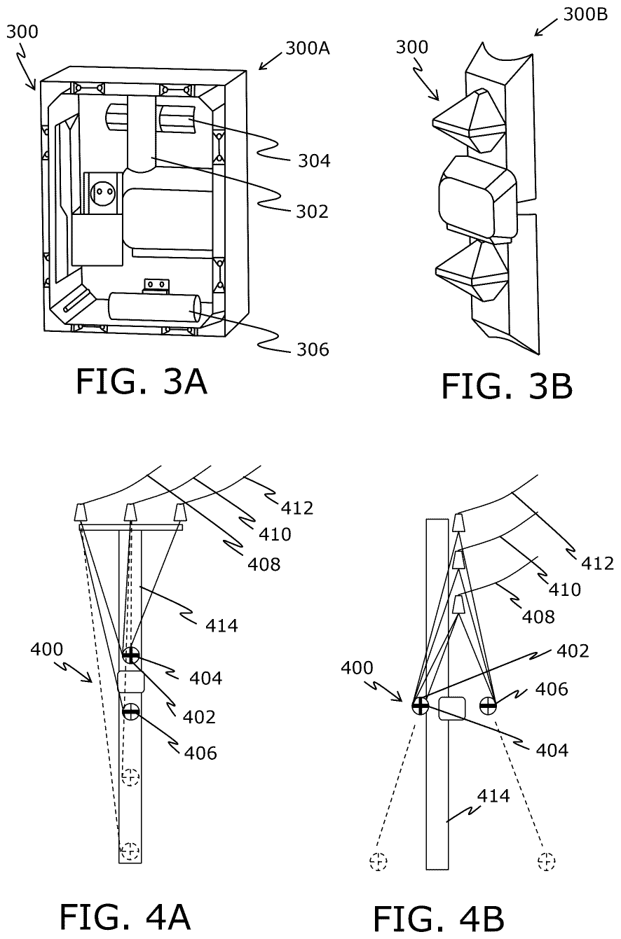

Referring to FIGS. 3A and 3B, illustrated are exemplary schematic illustrations of a housing of a sensing apparatus 300, in accordance with different embodiments of the present disclosure.

FIG. 3A is an exemplary schematic illustration of an integrated housing 300A of a sensing apparatus 300, in accordance with an embodiment of the present disclosure. Herein, components of the sensing apparatus 300, including at least a first sensor device 302, a second sensor device 304, and a third sensor device 306 are arranged in the same housing, as shown in the figure.

FIG. 3B is an exemplary schematic illustration of a distributed housing 300B of a sensing apparatus 300, in accordance with another embodiment of the present disclosure. Herein, components of the sensing apparatus 300 are divided and arranged in multiple distributed housing, as shown in the figure.

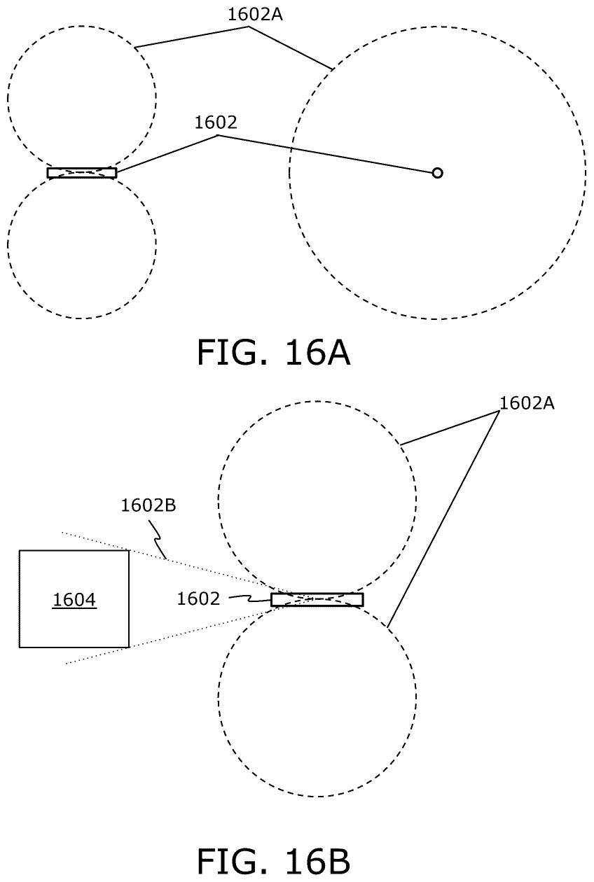

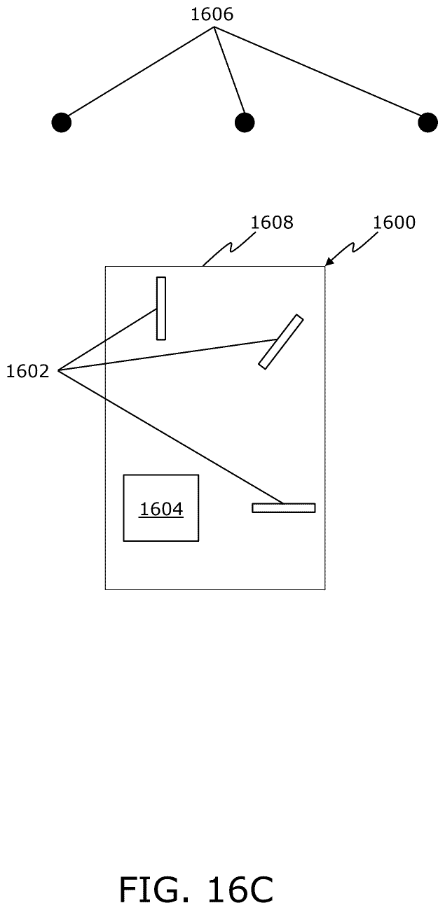

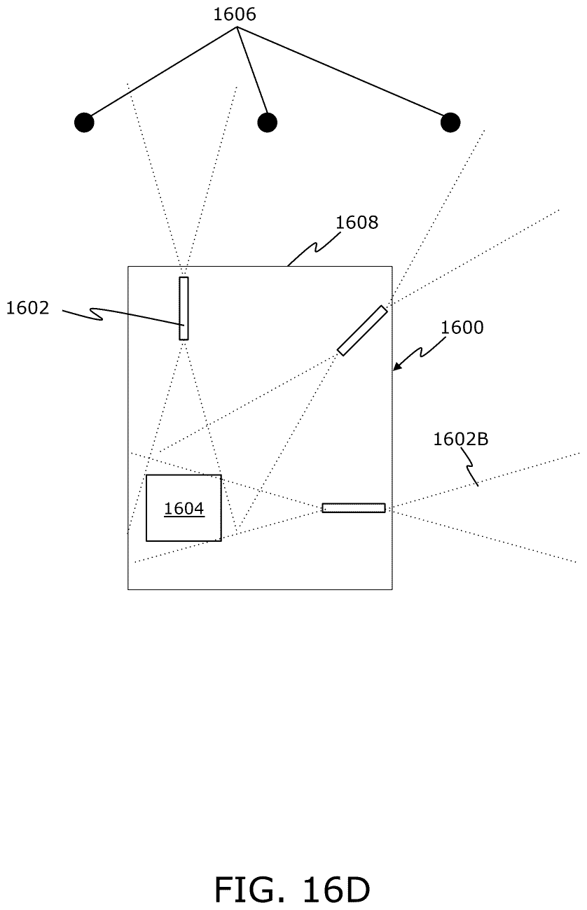

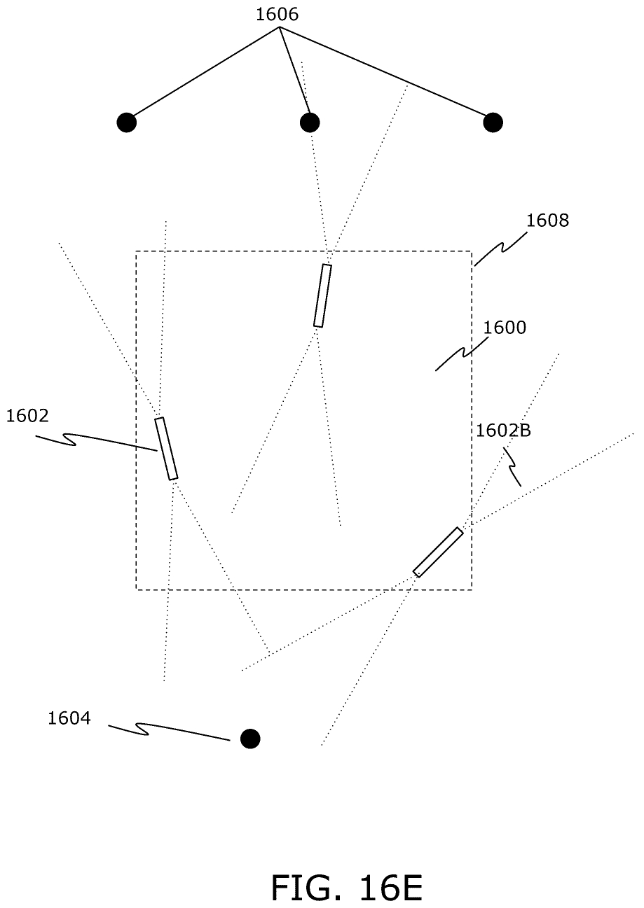

The devices and elements shown in FIGS. 3A and 3B may correspond to the devices and elements shown in FIGS. 16A-16E as follows. The reference numbers in parentheses refer to the reference numbers shown in FIGS. 16A-16E.

In FIG. 3A, the housing corresponds to the housing (1608) of the sensing apparatus (1600) described with reference to FIGS. 16A-16D. In the embodiment of FIG. 3A, a plurality of magnetic field sensor devices (1602) are arranged within the housing (1608). In the illustrated embodiment, three magnetic field sensor devices (1602) are arranged within the housing (1608) to sense a magnetic field in close proximity to the electrical overhead lines (1606) to generate the first sensor data. The housing (1608) further contains at least one internal magnetic noise source (1604), and at least one of the magnetic field sensor devices (1602) is oriented relative to the internal magnetic noise source (1604) such that a direction of minimum magnetic field sensitivity (1602B) of the magnetic field sensor device (1602) is aligned toward the internal magnetic noise source (1604), thereby reducing magnetic interference coupled from the internal magnetic noise source (1604) into the first sensor data.

In FIG. 3B, a plurality of magnetic field sensor devices (1602) are located outside the housing (1608). In the illustrated embodiment, three magnetic field sensor devices (1602) are located outside the housing (1608) and arranged to sense a magnetic field in close proximity to the electrical overhead lines (1606). Herein, the magnetic field sensors are connected to the processor in the housing via cable/bus. In such embodiments, at least one external magnetic noise source may be located outside the housing (1608), including at least one of a neutral wire, a ground wire, a low-voltage line, or communications cabling, and at least one of the magnetic field sensor devices (1602) is oriented such that the direction of minimum magnetic field sensitivity (1602B) is aligned toward the external magnetic noise source to reduce magnetic interference pickup while maintaining sensitivity to magnetic fields generated by the electrical overhead lines (1606).

FIGS. 4A and 4B illustrate arrangements of a sensing apparatus 400 with respect to an electrical pole 414, in accordance with different embodiments of the present disclosure. The sensing apparatus 400 comprises a first sensor device 402, a second sensor device 404, and a third sensor device 406. Based on the configuration of the sensing apparatus 400 with respect to the electrical pole 414, a configuration of electrical overhead lines 408, 410 and 412, also differs.

FIG. 4A illustrates a vertical arrangement of the sensing apparatus 400 with respect to the electrical pole 414. Herein, the electrical overhead lines 408, 410 and 412 are configured horizontally with respect to the electrical pole 414, as shown in the figure.

FIG. 4B illustrates a horizontal arrangement of the sensing apparatus 400 with respect to the electrical pole 414. Herein, the electrical overhead lines 408, 410 and 412 are configured vertically with respect to the electrical pole 414, as shown in the figure.

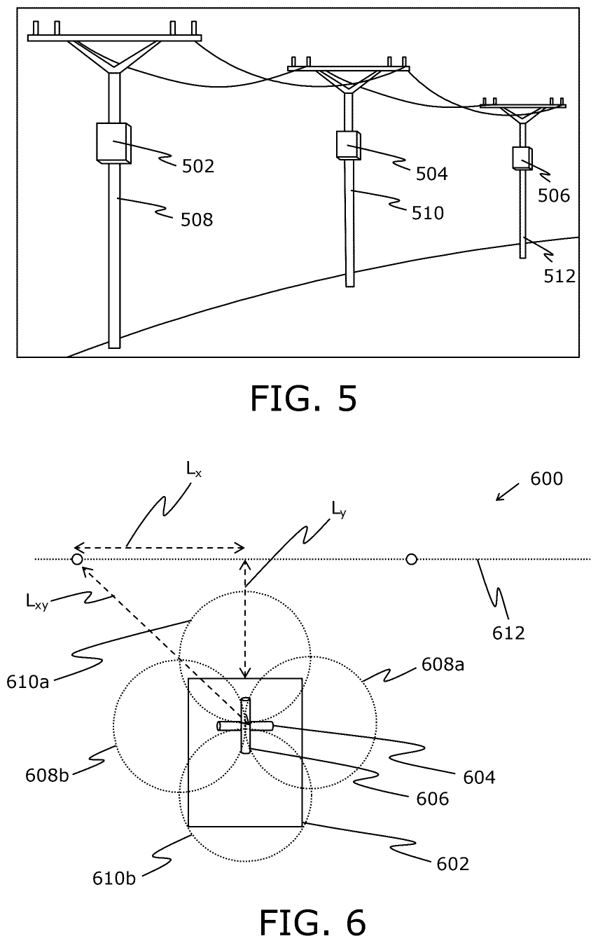

Referring to FIG. 5, illustrated is an exemplary schematic illustration of sensing apparatuses 502, 504, 506 with respect to electrical poles 508, 510, 512 of an electric utility grid, in accordance with an embodiment of the present disclosure. The sensing apparatuses 502, 504, 506 comprise sensor devices, which, in operation, sense magnetic field in close proximity to electrical overhead lines of an electric utility grid to generate sensor data. Herein, at least a portion of the sensing apparatuses 502, 504, 506 is arranged on an electrical pole 508, 510, 512 of the electric utility grid. As shown in the figure, the sensing apparatus 502 is arranged on the electrical pole 508, the sensing apparatus 504 is arranged on the electrical pole 510 and the sensing apparatus 506 is arranged on the electrical pole 512.

It may be understood by a person skilled in the art that the FIGS. 1, 2A, 2B, 3A, 3B, 4A, 4B and 5 are merely examples for sake of clarity, which should not unduly limit the scope of the claims herein. The person skilled in the art will recognize many variations, alternatives, and modifications of embodiments of the present disclosure.

FIG. 6 is an exemplary illustration of a measurement configuration 600 of a sensing apparatus 602, in accordance with an embodiment of the present disclosure. The sensing apparatus 602 comprises a first sensor device 604, and a second sensor device 606. The second sensor device 606 overlaps with the first sensor device 604 to form a cross-positioned two-sensor configuration as shown in the figure. Herein, at least a portion of the sensing apparatus 602 is arranged on an electrical pole of an electric utility grid. The sensor devices 604, 606, in operation, sense magnetic field with directional gain illustrated as 608a, 608b, 610a, 610b to an electrical overhead line 612 of an electric utility grid to generate sensor data. The sensor device 604 senses magnetic field in close proximity areas 608a, and 608b, and the sensor device 606 senses magnetic field in close proximity areas 610a, and 610b. Depending on distances Lₓ, L_{y}, L_{xy} between the electrical overhead line 612 and the sensor devices 604, 606, and with directional gain illustrated as 608a, 608b, 610a, 610b, directional gains of the sensor devices 604, 606 are calculated for generating the sensor data.

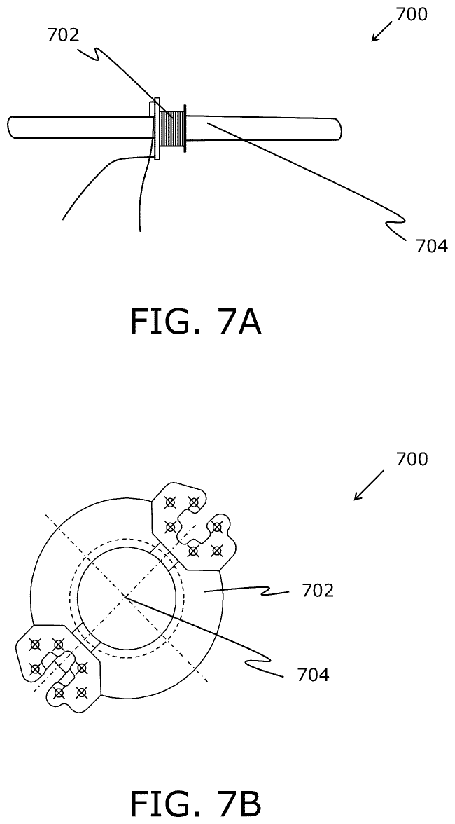

FIGS. 7A and 7B are exemplary illustrations of a magnetic field sensor 700, in accordance with an embodiment of the present disclosure. The magnetic field sensor 700 is implemented as a coil 702 wound around a ferrite core 704. FIG. 7A is an exemplary schematic illustration of a magnetic field sensor 700, in accordance with an embodiment of the present disclosure. FIG. 7B is a side profile of a magnetic field sensor 700, in accordance with an embodiment of the present disclosure.

It may be understood by a person skilled in the art that the FIGS. 6, 7A, and 7B are merely examples for sake of clarity, which should not unduly limit the scope of the claims herein. The person skilled in the art will recognize many variations, alternatives, and modifications of embodiments of the present disclosure.

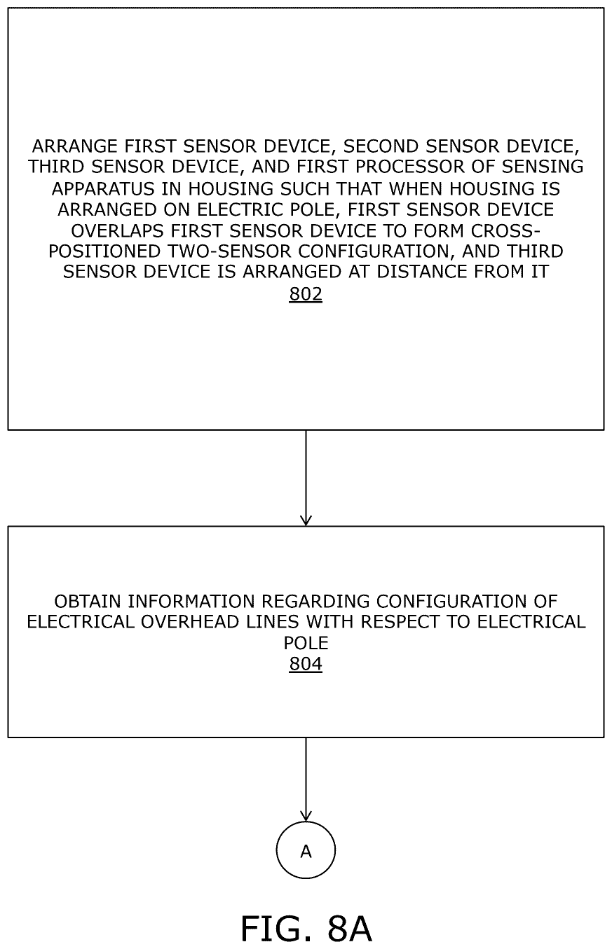

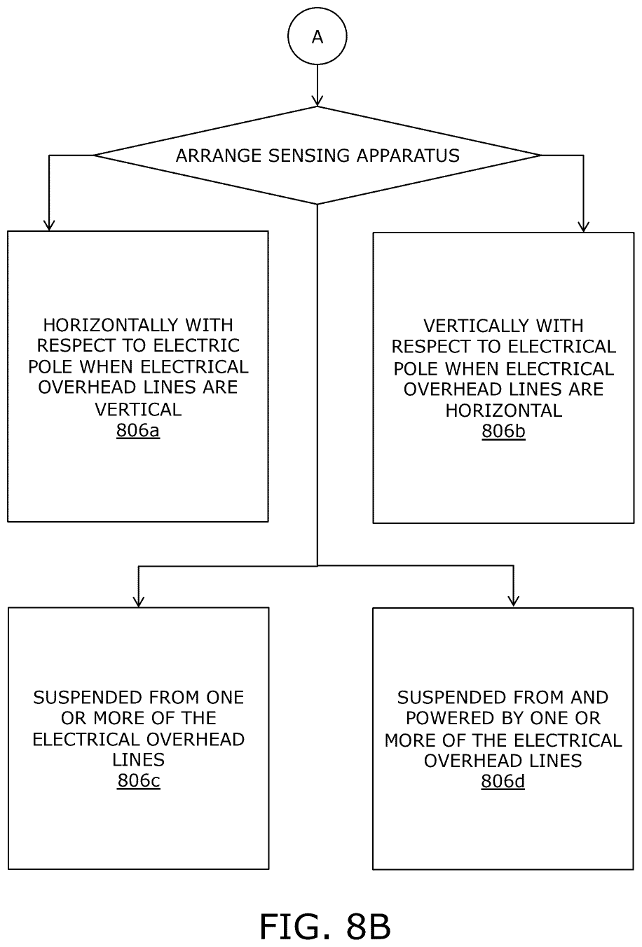

Referring to FIGS. 8A and 8B, illustrated are steps of a method for installing a sensing apparatus in an electric utility grid, in accordance with an embodiment of the present disclosure. At step 802, at least a first sensor device, a second sensor device, a third sensor device, and a first processor of the sensing apparatus are arranged in a housing such that when the housing is arranged on an electrical pole, the second sensor device overlaps with the first sensor device to form a cross-positioned two-sensor configuration, and the third sensor device is arranged at a distance from the cross-positioned two-sensor configuration. At step 804, information regarding a configuration of electrical overhead lines with respect to the electrical pole is obtained. Furthermore, the sensing apparatus is arranged based on the configuration of the electrical overhead lines, such that:
at step 806a, the sensing apparatus is arranged horizontally with respect to the electrical pole, when the configuration of the electrical overhead lines with respect to the electrical pole is a vertical configuration
at step 806b, the sensing apparatus is arranged vertically with respect to the electrical pole, when the configuration of the electrical overhead lines with respect to the electrical pole is a horizontal configuration;
at step 806c, the sensing apparatus is arranged to be suspended from one or more of the electrical overhead lines; or
at step 806d, the sensing apparatus is arranged to be suspended from one or more of the electrical overhead lines, such that the sensing apparatus is powered by the electrical overhead lines.

The steps 802 to 806 are only illustrative and other alternatives can also be provided where one or more steps are added, one or more steps are removed, or one or more steps are provided in a different sequence without departing from the scope of the claims herein.

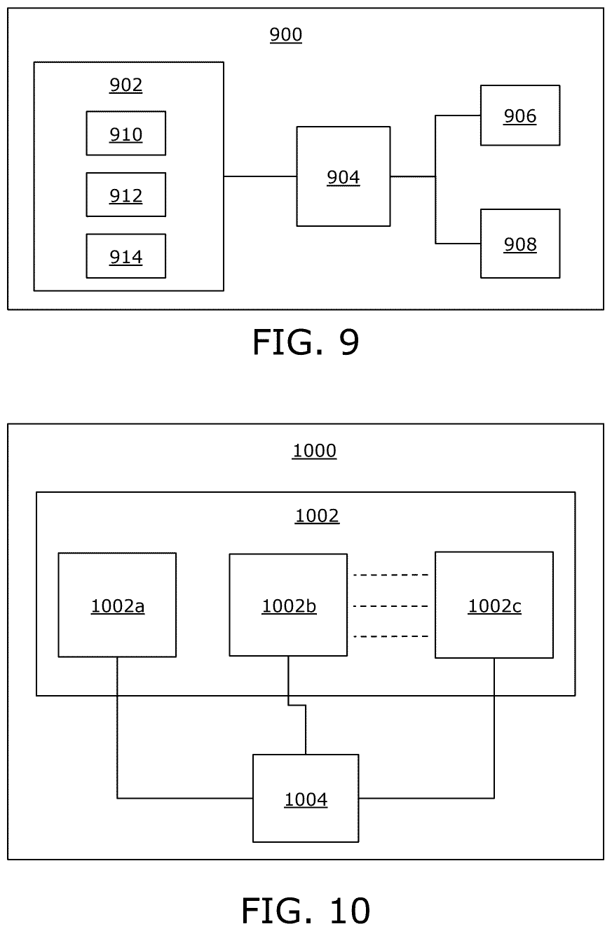

Referring to FIG. 9, illustrated is an architecture of a system 900 for monitoring and managing events and faults in an electric utility grid, in accordance with an embodiment of the present disclosure. The system 900 comprises a sensing apparatus 902, a first processor 904, a second processor 906, and a third processor 908. The sensing apparatus 902 comprises a first sensor device 910, a second sensor device 912, and a third sensor device 914. The sensing apparatus 902 is communicably coupled to the first processor 904. The first processor 904 is communicably coupled to the second processor 906 and the third processor 908.

Referring to FIG. 10, illustrated is an architecture of a system 1000 for monitoring and managing events and faults in an electric utility grid, in accordance with another embodiment of the present disclosure. The system 1000 comprises a sensing apparatus 1002 and a third processor 1004. The sensing apparatus 1002 comprises a plurality of sensing apparatuses 1002a, 1002b, 1002c.

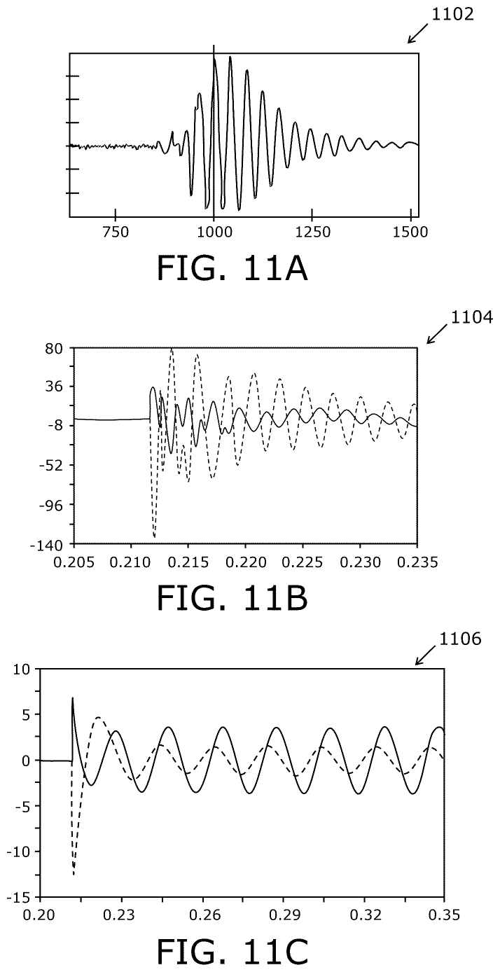

Referring to FIGS. 11A-11C, illustrated are different waveforms 1102, 1104, 1106 of current transients, in accordance with various embodiments of the present disclosure. FIG. 11A is a waveform 1102 of a load induced current transient. FIG. 11B is a waveform 1104 of a simulated current transient for a low impedance fault. FIG. 11C is a waveform 1106 of a simulated current transient for a high impedance fault.

It may be understood by a person skilled in the art that the FIGS. 9, 10, and 11 are merely examples for sake of clarity, which should not unduly limit the scope of the claims herein. The person skilled in the art will recognize many variations, alternatives, and modifications of embodiments of the present disclosure.

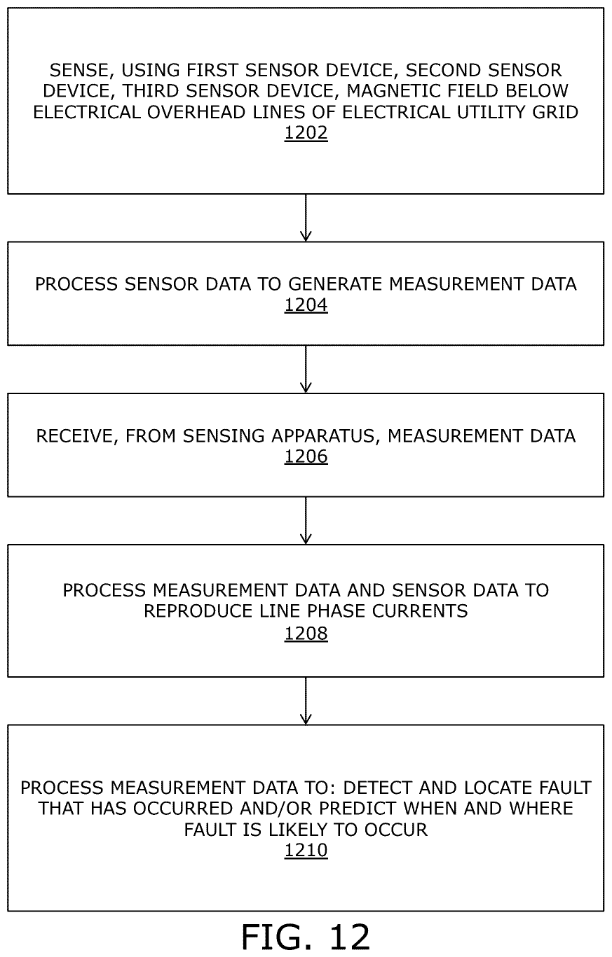

Referring to FIG. 12, illustrated are steps of a method for monitoring and managing events and faults in an electric utility grid, in accordance with an embodiment of the present disclosure. At step 1202, using at least a first sensor device, a second sensor device and a third sensor device of at least one sensing apparatus, magnetic field in close proximity to electrical overhead lines of the electric utility grid is sensed for generating sensor data. At step 1204, the sensor data is processed for generating measurement data, the measurement data comprising values of currents flowing through the electrical overhead lines. At step 1206, the measurement data is received from the at least one sensing apparatus. At step 1208, the measurement data and the measurement data are processed to reproduce line phase currents. At step 1210, the measurement data is processed for detecting and locating an event or a fault that has occurred in the electric utility grid and/or predicting when and where an event or a fault is likely to occur in the electric utility grid.

The steps 1202 to 1208 are only illustrative and other alternatives can also be provided where one or more steps are added, one or more steps are removed, or one or more steps are provided in a different sequence without departing from the scope of the claims herein.

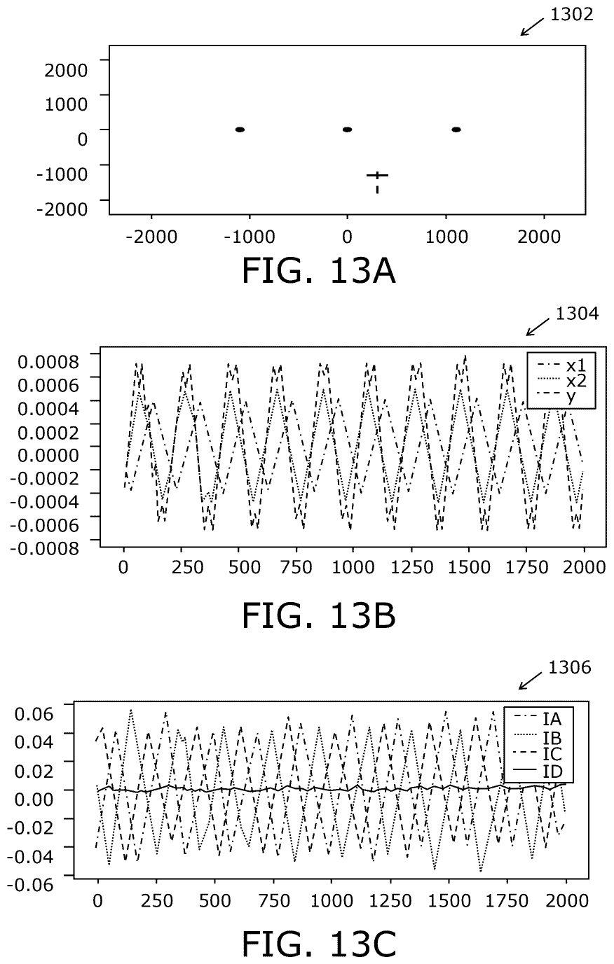

Referring to FIGS. 13A-13C, illustrated are exemplary simulations 1302, 1304, 1306 for a configuration of the sensing apparatus with respect to electrical overhead lines, in accordance with an embodiment of the present disclosure. FIG. 13A is an exemplary simulation 1302 of a line horizontal sensor having a top shift of 300 units and a turn of 90 units.

FIG. 13B is an exemplary simulation 1304 of a sampled waveform for the configuration of the sensing apparatus with respect to electrical overhead lines shown in FIG. 13A. FIG. 13C is an exemplary simulation 1306 of a resolved waveform for the configuration of the sensing apparatus with respect to electrical overhead lines shown in FIG. 13A.

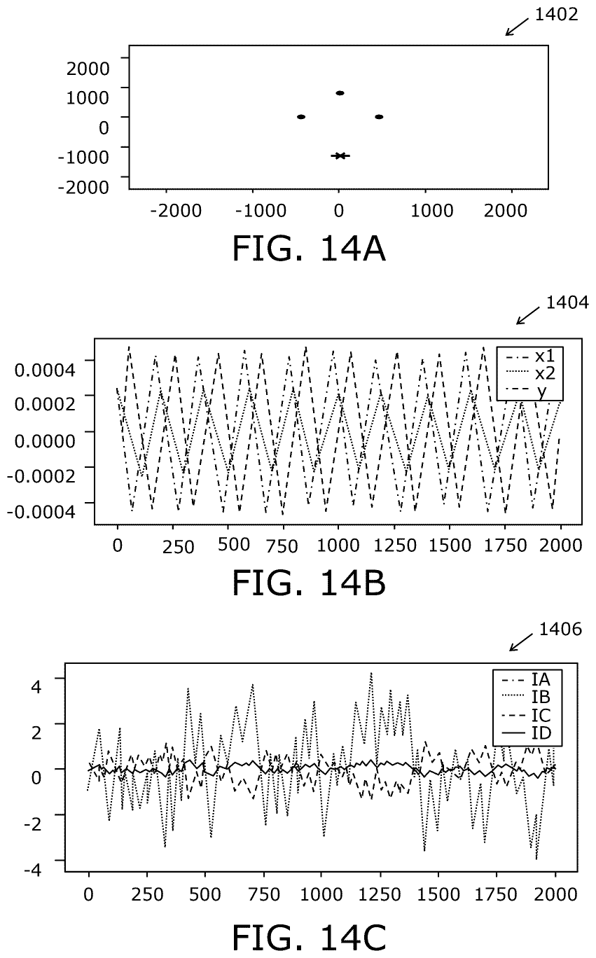

Referring to FIGS. 14A-14C, illustrated are exemplary simulations 1402, 1404, 1406 for a configuration of the sensing apparatus with respect to electrical overhead lines, in accordance with another embodiment of the present disclosure. FIG. 14A is an exemplary simulation 1402 of a line triangle sensor having a star 60 shift of 0 units and a turn of 0 units. FIG. 14B is an exemplary simulation 1404 of a sampled waveform for the configuration of the sensing apparatus with respect to electrical overhead lines shown in FIG. 14A. FIG. 14C is an exemplary simulation 1406 of a resolved waveform for the configuration of the sensing apparatus with respect to electrical overhead lines shown in FIG. 14A.

Referring to FIGS. 15A-15C, illustrated are exemplary simulations 1502, 1504, 1506 for a configuration of the sensing apparatus with respect to electrical overhead lines, in accordance with another embodiment of the present disclosure. FIG. 15A is an exemplary simulation 1502 of a line horizontal sensor having a top shift of 0 units and a turn of 0 units. FIG. 15B is an exemplary simulation 1504 of a sampled waveform for the configuration of the sensing apparatus with respect to electrical overhead lines shown in FIG. 15A. Herein, the sampled waveform represents sensor signals captured by the sensing apparatus. FIG. 15C is an exemplary simulation 1506 of a resolved waveform for the configuration of the sensing apparatus with respect to electrical overhead lines shown in FIG. 15A. Herein, the resolved waveform represents phase currents calculated from the sensor signals using an example of a matrix form.

Referring to FIGS. 16A-16D, illustrated are exemplary simulations for a configuration of the sensing apparatus 1600 for reducing electromagnetic interference, in accordance with yet another embodiment of the present disclosure. Shown in FIG. 16A, is an illustration depicting magnetic field lines 1602A of magnetic field sensor devices 1602. The magnetic field lines represent a reception strength or radiation pattern of the magnetic field sensor devices 1602 within which the magnetic field sensor devices 1602 is capable of detecting or sensing an external magnetic field, namely generated by the electrical overhead lines, wherein the reception strength varies with direction relative to the magnetic field sensor devices 1602, and wherein the reception strength includes at least one direction corresponding to a pickup minimum direction (i.e., a direction of minimum magnetic sensitivity, shown in FIGS. 16B and 16D) of the magnetic field sensor devices 1602.

Shown in FIG. 16B, is a magnetic noise source 1604 wherein each magnetic field sensor device 1602 is oriented relative to the internal magnetic noise source 1604 such that a direction of minimum magnetic field sensitivity 1602B of each magnetic field sensor device 1602 is aligned toward the internal magnetic noise source 1604. In FIG. 16C, illustrated is arrangement of the sensing apparatus 1600 with respect to the electrical overhead lines 1606. As shown, the magnetic noise source 1604 and the magnetic field sensor device 1602 are arranged within a housing 1608. FIG. 16D depicts the direction of minimum magnetic field sensitivity 1602B and the orientation of the internal magnetic noise source 1604 and the magnetic field sensor device 1602.

In an alternative embodiment, the magnetic noise source is located outside the housing, including a neutral wire, ground wire, low-voltage line, communications cabling, or conductors of another line, and the direction of minimum magnetic sensitivity is aligned toward the external magnetic noise source.

In an embodiment, shown in FIG. 16E, the magnetic noise source 1604 is located outside the housing 1608, the magnetic noise source including at least of: a neutral wire, ground wire, low-voltage line, communications cabling, or conductors of another line, and the direction of minimum magnetic sensitivity is aligned toward the external magnetic noise source. Herein, each magnetic field sensor device 1602 is oriented relative to the external magnetic noise source 1604, such as a neutral wire, such that a direction of minimum magnetic field sensitivity 1602B of each magnetic field sensor device 1602 is aligned toward the magnetic noise source 1604.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural.

1. A sensing apparatus comprising:
at least one magnetic field sensor device that, in operation, senses a magnetic field in close proximity to electrical overhead lines of an electric utility grid to generate a first sensor data, wherein at least a portion of the sensing apparatus is arranged on an electrical pole of the electric utility grid;
at least one magnetic noise source including at least one internal magnetic noise source arranged within a housing of the sensing apparatus or at least one external magnetic noise source located outside the housing;
at least one processor communicably coupled to the at least one magnetic field sensor device;
wherein the at least one magnetic field sensor device is oriented relative to the at least one magnetic noise source such that a direction of minimum magnetic field sensitivity of the at least one magnetic field sensor device is aligned toward the at least one magnetic noise source; and
wherein the at least one processor in operation:
pre-processes the first sensor data to generate measurement data, the measurement data comprising values of magnetic field produced by electrical currents flowing through the electrical overhead lines; and
utilizes the measurement data and the first sensor data to reproduce overhead line phase currents, and to detect and manage currents, events, and faults in the electric utility grid.

2. The sensing apparatus according to claim 1, wherein the at least one external magnetic noise source comprises at least one of: a neutral wire, a ground wire, a low-voltage line, communications cabling, and wires of another distribution line or transmission line.

3. The sensing apparatus according to claim 1, further comprising a ground-wire current sensor (208) to measure current through ground wire.

4. The sensing apparatus according to claim 1, wherein the arrangement of the sensing apparatus depends on a configuration of the electrical overhead lines with respect to the electrical pole, such that:
when the configuration of the electrical overhead lines with respect to the electrical pole is a horizontal configuration, the sensing apparatus is arranged vertically with respect to the electrical pole; and
when the configuration of the electrical overhead lines with respect to the electrical pole is a vertical configuration, the sensing apparatus is arranged horizontally with respect to the electrical pole.

5. The sensing apparatus according to claim 1, wherein the sensing apparatus is arranged to be suspended from one or more of the electrical overhead lines.

6. The sensing apparatus according to claim 5, wherein the sensing apparatus is powered by the electrical overhead lines.

7. The sensing apparatus according to claim 1, wherein a shortest distance between the sensing apparatus and the electrical overhead lines lies in a range of 500 millimetres-2 000 millimetres for distribution networks.

8. The sensing apparatus according to claim 1, wherein a shortest distance between the sensing apparatus and the electrical overhead lines lies in a range of 1000 millimetres-10 000 millimetres for transmission networks.

9. The sensing apparatus according to claim 1, wherein the housing enclosing the sensing apparatus is implemented as one of: an integrated housing, a distributed housing.

10. The sensing apparatus according to claim 9, wherein when the housing is the distributed housing, the at least one magnetic field sensor device, and the at least one magnetic noise source are arranged in proximity to the electrical pole.

11. The sensing apparatus according to claim 3, wherein the ground-wire current sensor is arranged on or around a ground wire of the electric utility grid or a neutral wire from amongst the electrical overhead lines.

12. The sensing apparatus according to claim 1, wherein the magnetic noise source (1604) comprises at least one of: a switched-mode power supply, a current converter, a radio-frequency transmitter, a cellular communication module, a wireless communication circuit.

13. The sensing apparatus according to claim 1, wherein the at least one magnetic field sensor device comprises: a first magnetic field sensor device, a second magnetic field sensor device, a third magnetic field sensor device, and wherein the first magnetic field sensor device, the second magnetic field sensor device, and the third magnetic field sensor device are oriented at mutually different angles relative to each other.

14. The sensing apparatus according to claim 13, wherein a given magnetic field sensor device is coupled to a measurement apparatus arranged in a circuit including the given magnetic field sensor device, wherein the measurement apparatus, in operation, measures an induced current in the circuit, the sensor data comprising values of the induced current in the circuit,
wherein when processing the sensor data to generate the measurement data, the at least one processor is configured to:
determine values of magnetic field densities produced by electrical current in the electrical overhead lines; and
determine the values of currents flowing through the electrical overhead lines, based on the values of the magnetic field densities measured by the sensors and the directivity and orientation of the sensors and distance and position of the electrical overhead lines from the sensors.

15. The sensing apparatus according to claim 1, wherein the at least one processor is implemented at least partially as a cloud-based processor communicably coupled to the sensing apparatus.

16. A method for reducing electromagnetic interference in a sensing apparatus installed on an electrical pole of an electric utility grid, the method comprising:
identifying at least one magnetic noise source located within a housing of the sensing apparatus or outside the housing of the sensing apparatus;
determining a direction of minimum magnetic field sensitivity of each magnetic field sensor device within the housing;
orienting the at least one magnetic field sensor device relative to the at least one magnetic noise source such that a direction of minimum magnetic field sensitivity of the at least one magnetic field sensor device is aligned toward the at least one magnetic noise source; and
sensing magnetic fields generated by electrical overhead lines while reducing electromagnetic interference from the magnetic noise source.

17. A method for installing a sensing apparatus in an electric utility grid, comprising:
arranging at least one magnetic field sensor device, at least one magnetic noise source including at least one internal magnetic noise source or at least one external magnetic noise source, and at least one processor of the sensing apparatus in a housing when the housing is arranged on an electrical pole;
obtaining information regarding a configuration of electrical overhead lines with respect to the electrical pole; and
arranging the sensing apparatus based on the configuration of the electrical overhead lines, such that:
the sensing apparatus is arranged horizontally with respect to the electrical pole, when the configuration of the electrical overhead lines with respect to the electrical pole is a vertical configuration;
the sensing apparatus is arranged vertically with respect to the electrical pole, when the configuration of the electrical overhead lines with respect to the electrical pole is a horizontal configuration;
the sensing apparatus is arranged to be suspended from one or more of the electrical overhead lines; or
the sensing apparatus is arranged to be suspended from one or more of the electrical overhead lines, such that the sensing apparatus is powered by the electrical overhead lines.

18. The method according to claim 16, wherein the sensing apparatus is installed between the electrical overhead lines and a surface upon which the electrical pole is installed, wherein a shortest distance between the sensing apparatus and the electrical overhead lines lies in a range of 1500 millimetres-10000 millimetres for transmission networks.

19. A system for reducing electromagnetic interference in a sensing apparatus installed on an electrical pole of an electric utility grid and for monitoring and managing events and faults in an electric utility grid, the system comprising:
at least one sensing apparatus comprising:
at least one magnetic field sensor device that, in operation, senses magnetic field in close proximity to electrical overhead lines of an electric utility grid to generate a first sensor data, wherein at least a portion of the sensing apparatus is arranged on an electrical pole of the electric utility grid;
at least one magnetic noise source including at least one internal magnetic noise source arranged within a housing of the sensing apparatus or at least one external magnetic noise source located outside the housing;
at least one processor communicably coupled to the at least one magnetic field sensor device;
wherein the at least one magnetic field sensor device is oriented relative to the at least one magnetic noise source such that a direction of minimum magnetic field sensitivity of the at least one magnetic field sensor device is aligned toward the at least one magnetic noise source; and
wherein the at least one processor in operation:
identifies the at least one magnetic noise source of the sensing apparatus to determine a direction of minimum magnetic field sensitivity of at least one magnetic field sensor for orienting the magnetic field sensor such that the direction of minimum magnetic field sensitivity is aligned toward the magnetic noise source;
pre-processes the first sensor data to generate measurement data, the measurement data comprising values of magnetic field produced by electrical currents flowing through the electrical overhead lines;
utilizes the measurement data and the first sensor data to reproduce overhead line phase currents, to detect, classify and locate an event or a fault that has occurred in the electric utility grid; and/or
predicts when and where an event or a fault is likely to occur in the electric utility grid; and
alerts a network operator of the detected or predicted event or fault and its location.

20. The system according to claim 19, wherein the sensing apparatus further comprises a geolocation device, wherein the geolocation device provides location information of the sensing apparatus and timing information of the measurement data.

21. The system according to claim 20, wherein when utilizing the measurement data, the at least one processor is configured to:
detect a current transient, based on the measurement data, wherein the current transient indicates that an event or a fault has occurred in the electric utility grid;
determine a first location and a first time instant at which the current transient occurs, based on the location information and the timing information, respectively; and
determine a second location of the current transient at a second time instant, based at least on the first location, the first time instant, and a pre-known current propagation speed in the electrical overhead lines, wherein the second time instant is later than the first time instant.

22. The system according to claim 19, wherein the at least one processor, in operation,
detects a high-frequency transient associated with a fault in the electrical overhead lines,
determines an arrival time of the high-frequency transient at each of two or more spatially separated sensing apparatuses, and
determines a fault location along the electrical overhead lines based on a difference between the arrival times and a predefined propagation speed of the electrical overhead lines.

23. A method for monitoring and managing events and faults in an electric utility grid, the method comprising:
sensing, using at least one magnetic field sensor device of a sensing apparatus, a magnetic field in close proximity to electrical overhead lines of the electric utility grid for generating a first sensor data, wherein the sensing apparatus being at least partially arranged on an electrical pole;
processing, by at least one processor of the sensing apparatus, the first sensor data to generate measurement data, the measurement data comprising values of magnetic field produced by electrical currents flowing through the electrical overhead lines;
utilizing the measurement data and the first sensor data to reproduce overhead line phase currents; and
processing the measurement data to:
detect and locate an event or a fault that has occurred in the electric utility grid; and/or
predict when and where an event or a fault is likely to occur in the electric utility grid.

24. The method according to claim 23, further comprising:
detecting a high-frequency transient associated with a fault in the electrical overhead lines;
time stamping the detected high-frequency transient at two or more spatially separated sensing apparatuses; and
determining a fault location along the electrical overhead lines based on a difference between arrival times of the high-frequency transient and a predefined propagation speed of the electrical overhead lines.
